(19) United States
(12) Patent Application Publication
(10) Pub. No.: US 2017/0206165 A1
(43) Pub. Date: Jul. 20, 2017

(54) METHOD FOR ACCESSING HETEROGENEOUS MEMORIES AND MEMORY MODULE INCLUDING HETEROGENEOUS MEMORIES

(71) Applicant: Samsung Electronics Co., Ltd., Suwon-si (KR)

(72) Inventor: Sun-Young Lim, Hwaseong-si (KR)

(21) Appl. No.: 15/403,730

(22) Filed: Jan. 11, 2017

Related U.S. Application Data
(60) Provisional application No. 62/278,610, filed on Jan. 14, 2016.

(30) Foreign Application Priority Data
Jan. 22, 2016 (KR) 10-2016-0008210
Jan. 22, 2016 (KR) 10-2016-0008214
Mar. 11, 2016 (KR) 10-2016-0029743

(51) Int. Cl. G06F 12/0877; G11C 8/08

(52) U.S. Cl. CPC G06F 12/0877; G11C 8/08; G06F 2212/60; G06F 2212/205

(57) ABSTRACT

A method of accessing volatile memory devices, nonvolatile memory devices, and a controller controlling the volatile memory devices and the nonvolatile memory devices is provided. The method includes receiving, by the controller, a row address associated with the volatile memory devices and the nonvolatile memory devices through first lines at a first timing, receiving, by the controller, an extended address associated with the nonvolatile memory devices through second lines at a second timing, and receiving, by the controller, a column address associated with the nonvolatile memory devices and the volatile memory devices through third lines at a third timing.

### REFERENCE TO PRIORITY APPLICATIONS

A claim for priority under 35 U.S.C. §119 is made to U.S. Patent Provisional No. 62/278,610, filed Jan. 14, 2016, in the U.S. Patent and Trademark Office, Korean Patent Application No. 10-2016-0008210, filed Jan. 22, 2016, in the Korean Intellectual Property Office, Korean Patent Application No. 10-2016-0008214, filed Jan. 22, 2016, in the Korean Intellectual Property Office, and Korean Patent Application No. 10-2016-0029743, filed Mar. 11, 2016, in the Korean Intellectual Property Office, the entire contents of which are hereby incorporated herein by reference.

### BACKGROUND

The inventive concept relates to semiconductor memory devices and, more particularly, to methods for accessing heterogeneous memories and a memory module including heterogeneous memories.

A semiconductor memory refers to a memory device that is implemented using semiconductor such as silicon (Si), germanium (Ge), gallium arsenide (GaAs), indium phosphide (InP), or the like. Semiconductor memory devices are typically classified as volatile memory devices or nonvolatile memory devices.

A volatile memory device refers to a memory device which loses data stored therein at power-off. The volatile memory device includes a static random access memory (SRAM), a dynamic ram (DRAM), a synchronous DRAM or the like. A nonvolatile memory device refers to a memory device which retains data stored therein even at power-off. The nonvolatile memory device includes a read only memory (ROM), a programmable ROM (PROM), an electrically programmable ROM (EPROM), an electrically erasable and programmable ROM (EEPROM), a flash memory device, a phase-change RAM (PRAM), a magnetic RAM (MRAM), a resistive RAM (RRAM), a ferroelectric RAM (FRAM), or the like.

Since a response speed and an operation speed of the DRAM are typically very fast, the DRAM is widely used as a main memory of a system. However, since the DRAM is a volatile memory in which data is lost when power is shut off, a separate device is used to retain data stored in the DRAM. In addition, since the DRAM stores data using capacitors, the size of a unit cell is typically large, thereby making it difficult to increase a DRAM capacity within a restricted area.

### SUMMARY

Embodiments of the inventive concept provide a nonvolatile memory module having a great capacity and high performance by using a nonvolatile memory and a volatile memory.

One aspect of embodiments of the inventive concept is directed to provide a method of accessing volatile memory devices, nonvolatile memory devices, and a controller controlling the volatile memory devices and the nonvolatile memory devices, the method including receiving, by the controller, a row address associated with the volatile memory devices and the nonvolatile memory devices through first lines at a first timing; receiving, by the controller, an extended address associated with the nonvolatile memory devices through second lines at a second timing; and receiving, by the controller, a column address associated with the nonvolatile memory devices and the volatile memory devices through third lines at a third timing. The first lines include the second lines and the third lines.

Another aspect of embodiments of the inventive concept is directed to provide a memory module, which includes nonvolatile memory devices; volatile memory devices; and a controller configured to control the nonvolatile memory devices and the volatile memory devices, wherein the controller receives a row address associated with the volatile memory devices and the nonvolatile memory devices through first lines at a first timing, receives an extended address associated with the nonvolatile memory devices through second lines at a second timing, and receives a column address associated with the nonvolatile memory devices and the volatile memory devices through third lines at a third timing.

Still another aspect of embodiments of the inventive concept is directed to provide a method of accessing a cache memory of a first type and a main memory of a second type, the method including sending a common address to the cache memory of the first type and the main memory of the second type through address lines associated with the cache memory of the first type by using a plurality of sequences; and sending an extended address to the main memory of the second type through the address lines associated with the cache memory of the first type by using at least one sequence.

According to still further embodiments of the invention, methods of operating memory systems containing volatile and nonvolatile memory devices therein include providing a memory controller with a row address associated with the volatile and nonvolatile memory devices, via first address lines, concurrently with providing an active command. Next, after a first time interval has transpired since the row address has been provided, the memory controller is provided with a column address associated with the volatile and nonvolatile memory devices, via at least some of the first address lines. In addition to the column address, a nonvolatile extended block address is provided concurrently via at least additional ones of the first address lines. The providing the memory controller with a column address may also be performed concurrently with providing the memory controller with an activation extension command, via at least some of the first address lines.

According to some further embodiments of the invention, operations may be performed to read a tag from the volatile memory device and then compare the tag to the nonvolatile extended block address to determine an equivalency therebetween. Still further operations may be performed to write a dirty flag having a dirty state concurrently with writing data into the volatile memory device. In addition, reading a tag from the volatile memory device and comparing the tag to the nonvolatile extended block address to determine a non-equivalency therebetween may be followed by reading a dirty flag from the volatile memory device.

### BRIEF DESCRIPTION OF THE FIGURES

The above and other objects and features will become apparent from the following description with reference to the following figures, wherein like reference numerals refer to like parts throughout the various figures unless otherwise specified, and wherein:

FIG. 1 is a block diagram illustrating a user system according to an embodiment of the inventive concept;

FIG. 2 is a block diagram illustrating a nonvolatile memory module of FIG. 1;

FIG. 3 is a timing diagram illustrating a process in which a command and an address are sent to a nonvolatile memory module based on a DIMM or NVDIMM;

FIG. 4 is a flowchart illustrating an operating method of a nonvolatile memory module, according to an embodiment of the inventive concept;

FIG. 5 is a flowchart illustrating a method in which a nonvolatile memory module writes data under control of a processor;

FIG. 6 is a flowchart illustrating a method in which a nonvolatile memory module reads data under control of a processor;

FIGS. 7 and 8 illustrate examples in which an extended address is sent according to applications of the inventive concept;

FIG. 9 is a timing diagram illustrating an application of a process in which a command and an address are sent to a nonvolatile memory module based on a DIMM or NVDIMM;

FIG. 10 is a flowchart illustrating a method in which a nonvolatile memory module obtains the row address, an extended address, and a column address from an extended active command;

FIG. 11 is a block diagram illustrating a nonvolatile memory module of FIG. 1 according to another embodiment of the inventive concept;

FIG. 12 is a flowchart illustrating an operation of a nonvolatile memory module of FIG. 11;

FIG. 13 is a view for describing a cache structure of a volatile memory of FIG. 11;

FIG. 14 is a timing diagram for describing a read operation of FIG. 12 in detail;

FIG. 15 is a timing diagram illustrating an implementation of data and validity information of FIG. 14;

FIG. 16 is a timing diagram for describing, in detail, a read operation of FIG. 12;

FIG. 17 is a timing diagram illustrating an implementation of data and validity information of FIG. 16;

FIG. 18 is a block diagram illustrating other features of a memory module, according to another embodiment of the inventive concept;

FIG. 19 is a flowchart illustrating a handshaking procedure between a processor and a nonvolatile memory module of FIG. 18;

FIG. 20 is a timing diagram for describing a handshaking operation of FIG. 19 in detail;

FIG. 21 is a block diagram illustrating a memory module of FIG. 1, according to another embodiment of the inventive concept;

FIG. 22 is a block diagram illustrating a nonvolatile memory module of FIG. 1, according to another embodiment of the inventive concept;

FIG. 23 is a block diagram illustrating a nonvolatile memory module of FIG. 1, according to another embodiment of the inventive concept;

FIG. 24 is a block diagram illustrating a nonvolatile memory module of FIG. 1, according to another embodiment of the inventive concept;

FIG. 25 is a block diagram illustrating a nonvolatile memory module of FIG. 1, according to another embodiment of the inventive concept;

FIG. 26 is a block diagram illustrating a nonvolatile memory module of FIG. 1, according to another embodiment of the inventive concept;

FIG. 27 is a block diagram illustrating a nonvolatile memory module of FIG. 1, according to another embodiment of the inventive concept;

FIG. 28 is a block diagram illustrating a nonvolatile memory module of FIG. 1, according to another embodiment of the inventive concept;

FIG. 29 is a block diagram illustrating a nonvolatile memory module of FIG. 1, according to another embodiment of the inventive concept;

FIG. 30 is a block diagram illustrating a nonvolatile memory module of FIG. 1, according to another embodiment of the inventive concept;

FIG. 31 is a block diagram illustrating a nonvolatile memory included in a nonvolatile memory module, according to the inventive concept;

FIG. 32 is a view illustrating a cell structure and a physical property of a phase change memory device as an example of a nonvolatile memory device according to an embodiment of the inventive concept;

FIGS. 33 to 34 are views illustrating a memory cell included in a nonvolatile memory according to an embodiment of the inventive concept;

FIG. 35 is a block diagram illustrating a volatile memory of a nonvolatile memory module according to an embodiment of the inventive concept.

FIG. 36 is a block diagram illustrating a user system to which a nonvolatile memory module according to an embodiment of the inventive concept is appli; and

FIG. 37 is a view illustrating a server system to which a nonvolatile memory system according to an embodiment of the inventive concept is applied.

### DETAILED DESCRIPTION

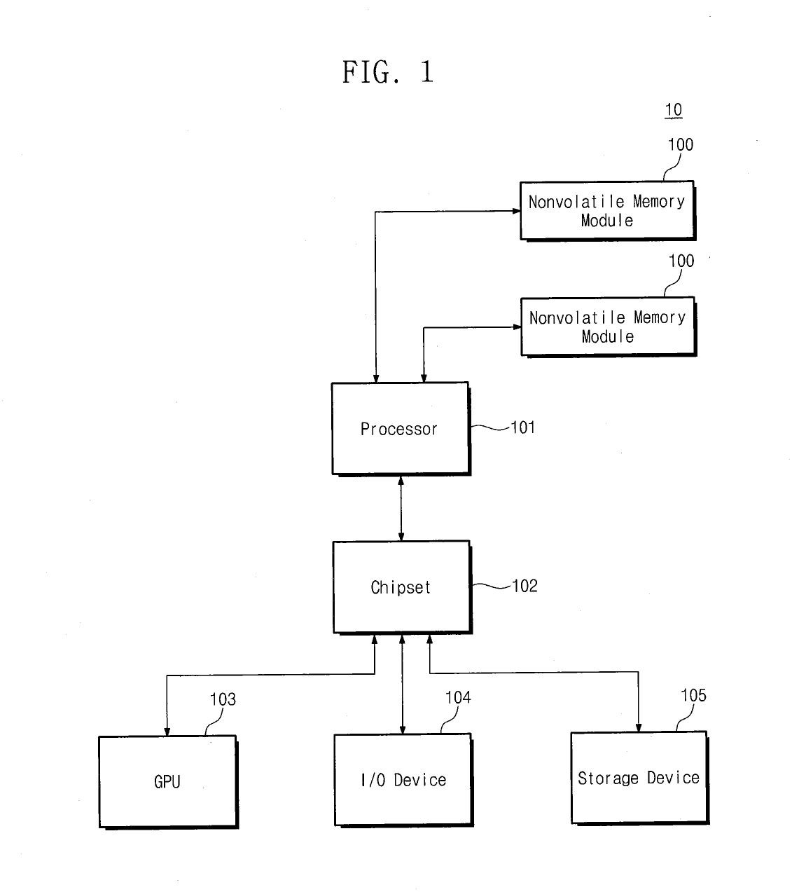

FIG. 1 is a block diagram illustrating a user system according to an embodiment of the inventive concept. Referring to FIG. 1, the user system 10 includes nonvolatile memory modules 100, a processor 101, a chipset 102, a graphic processing unit (GPU) 103, an input/output device 104, and a storage device 105. In an embodiment, the user system 10 may be a computing system such as a computer, a notebook, a server, a workstation, a portable communication terminal, a personal digital assistant (PDA), a portable multimedia player (PMP), a smartphone, or a wearable device.

The processor 101 may control an overall operation of the user system 100. The processor 101 may perform various operations of the user system 100 and may process data.

The nonvolatile memory modules 100 may be directly connected to the processor 101. For example, each of the nonvolatile memory modules 100 may have a form of a dual in-line memory module (DIMM) and may be mounted in a DIMM socket directly connected to the processor 101 to communicate with the processor 101. In an embodiment, each of the nonvolatile memory modules 100 may communicate with the processor 101 based on a NVDIMM protocol.

Each of the nonvolatile memory modules 100 may be used as a main memory or a working memory (or operating memory). Each of the nonvolatile memory modules 100 may include a nonvolatile memory and a volatile memory. The nonvolatile memory includes a memory, which does not lose data stored therein even at power-off, such as a read only memory (ROM), a programmable ROM (PROM), an electrically programmable ROM (EPROM), an electrically erasable and programmable ROM (EEPROM), a flash memory, a phase-change RAM (PRAM), a magnetic RAM (MRAM), a resistive RAM (RRAM), or a ferroelectric RAM (FRAM). The volatile memory may include a memory, which loses data stored therein at power-off, such as a static RAM (SRAM), a dynamic RAM (DRAM), or a synchronous DRAM (SDRAM).

In an embodiment, the nonvolatile memory of each nonvolatile memory module 100 may be used as a main memory of the user system 10 or the processor 101, and the volatile memory thereof may be used as a cache memory of the user system 10, the processor 101, or a corresponding nonvolatile memory module 100.

The chipset 102 may be electrically connected to the processor 101 and may control hardware of the user system 10 under control of the processor 101. For example, the chipset 102 may be connected to the GPU 103, the input/output device 104, and the storage device 105 through main buses respectively and may perform a bridge operation with respect to the main buses.

The GPU 103 may perform a series of arithmetic operations for outputting image data of the user system 10. In an embodiment, the GPU 103 may be embedded in the processor 101 in the form of a system-on-chip (SoC).

The input/output device 104 may include various devices that make it possible to input data or an instruction to the user system 10 or to output data to an external device. For example, the input/output device 104 may include user input devices such as a keyboard, a keypad, a button, a touch panel, a touch screen, a touch pad, a touch ball, a camera, a microphone, a gyroscope sensor, a vibration sensor, a piezoelectric element, a temperature sensor, and a biometric sensor and user output devices such as a liquid crystal display (LCD), an organic light emitting diode (OLED) display device, an active matrix OLED (AMOLED) display device, a light emitting diode (LED), a speaker, and a motor.

The storage device 105 may be used as a mass storage medium of the user system 10. The storage device 105 may include mass storage media such as a hard disk drive (HDD), a solid state drive (SSD), a memory card, and a memory stick.

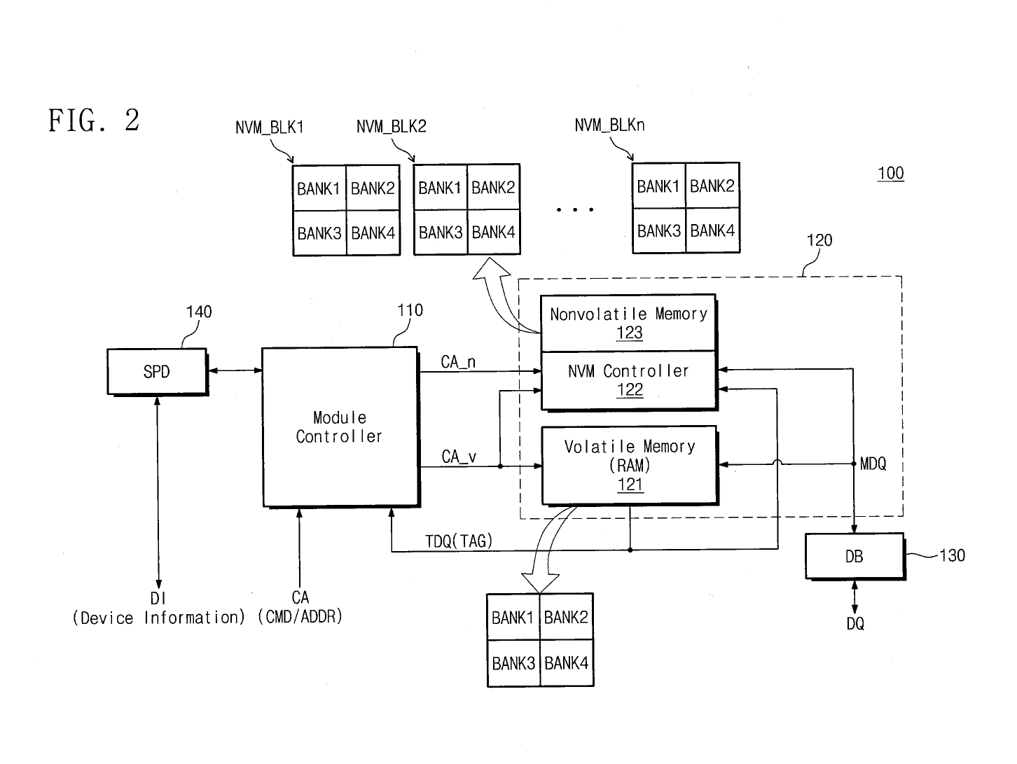

FIG. 2 is a block diagram illustrating a nonvolatile memory module of FIG. 1. Referring to FIGS. 1 and 2, the nonvolatile memory module 100 includes a module controller 110, a heterogeneous memory device 120, a data buffer (DB) 130, and a serial presence detect chip (SPD) 140.

The module controller 110 may receive a command/address CA from the processor 101 and may control the heterogeneous memory device 120 in response to the received command/address CA. For example, the module controller 110 may provide the heterogeneous memory device 120 with a command/address CA_n and a command/address CA_v in response to the command/address CA from the processor 101.

In an embodiment, the command/address CA_n may be a command/address for controlling a nonvolatile memory 123 included in the heterogeneous memory device 120, and the command/address CA_v may be a command/address for controlling a volatile memory 121 included in the heterogeneous memory device 120.

Below, for descriptive convenience, the command/address CA from the processor 101 may be referred to as “module command/address”, the command/address CA_v provided from the module controller 110 to the volatile memory 121 may be referred to as “volatile memory (VM) command/address”, and the command/address CA_n provided from the module controller 110 to an nonvolatile memory (NVM) controller 122 may be referred to as “nonvolatile memory (NVM) command/address”.

In an embodiment, the NVM command/address CA_n and the VM command/address CA_V may be provided through different command/address buses.

In an embodiment, the module controller 110 may be a register clock driver (RCD).

The heterogeneous memory device 120 may include the volatile memory 121, the NVM controller 122, and the nonvolatile memory 123. The volatile memory 121 may operate in response to the VM command/address CA_v from the module controller 110. The volatile memory 121 may output data and a tag “TAG” through a memory data line MDQ and a tag data line TDQ respectively in response to the VM command/address CA_v. The volatile memory 121 may write data and a tag respectively received through the memory data line MDQ and the tag data line TDQ based on the VM command/address CA_v.

The NVM controller 122 may operate in response to the NVM command/address CA_n from the module controller 110. For example, on the basis of the NVM command/address CA_n from the module controller 110, the NVM controller 122 may program data received through the memory data line MDQ in the nonvolatile memory 123 or may output data programmed in the nonvolatile memory 123 through the memory data line MDQ.

The NVM controller 122 may perform various operations for controlling the nonvolatile memory 123. For example, the NVM controller 122 may perform operations such as garbage collection, wear leveling, and address conversion, to use the nonvolatile memory 123 effectively. In an embodiment, the NVM controller 122 may further include elements such as an error correction circuit and a randomizer.

In an embodiment, the NVM controller 122 may use an address, which is included in a received NVM command/address CA_n, as a logical address for the nonvolatile memory 123. The NVM controller 122 may convert the logical address into a physical address of the nonvolatile memory 123 and may send the converted physical address to the nonvolatile memory 123. Also, the NVM controller 122 may convert a command, which is included in the received NVM command/address CA_n, into a command for the nonvolatile memory 123 and may send the converted command to the nonvolatile memory 123. In an embodiment, the NVM controller 122 may provide the nonvolatile memory 123 with the converted physical address and command through a line that is separate from a memory data line MDQ, a tag data line TDQ, a line through which the NVM command/address CA_n is sent, and a line through which a VM command/address CA_v is sent.

In an embodiment, the volatile memory 121 and the NVM controller 122 may share the same memory data line MDQ.

In an embodiment, the volatile memory 121 and the module controller 110 may share the tag data line TDQ. Alternatively, the volatile memory 121, the NVM controller 122, and the module controller 110 may share the tag data line TDQ. The NVM controller 122 or module controller 110 may output a tag “TAG” through the tag data line TDQ or may receive the tag “TAG” through the tag data line TDQ.

The data buffer 130 may receive data through the memory data line MDQ and may provide the received data to the processor 101 through a data line DQ. Alternatively, the data buffer 130 may receive data through the data line DQ and may output the received data through the memory data line MDQ. In an embodiment, the data buffer 130 may operate in response to control of the module controller 110 (e.g., a buffer command (not shown)). In an embodiment, the data buffer 130 may distinguish a signal on the memory data line MDQ and a signal on the data line DQ. Alternatively, the data buffer 130 may block a signal between the memory data line MDQ and the data line DQ. That is, a signal of the memory data line MDQ may not affect the data line DQ by the data buffer 130, or a signal of the data line DQ may not affect the memory data line MDQ by the data buffer 130.

In an embodiment, the memory data line MDQ may be a data transmission path among elements included in the nonvolatile memory (e.g., a volatile memory, a nonvolatile memory, a data buffer, etc.), and the data line DQ may be a data transmission path between the nonvolatile memory module 100 and the processor 101. The tag data line TDQ may be a transmission path for sending and receiving a tag “TAG”.

In an embodiment, each of the memory data line MDQ, the data line DQ, and the tag data line TDQ may include a plurality of wires. Furthermore, although not shown, each of the memory data line MDQ, the data line DQ, and the tag data line TDQ may include a memory data strobe line MDQS, a data strobe line DQS, and a tag data strobe line TDQS. Below, for ease of illustration, reference numerals and configurations of the memory data strobe line MDQS, the data strobe line DQS, and the tag data strobe line TDQS are omitted. However, embodiments of the inventive concept may not be limited thereto. For example, elements connected with the memory data strobe line MDQS, the data strobe line DQS, and the tag data strobe line TDQS may send and receive data or tags in synchronization with signals of the memory data strobe line MDQS, the data strobe line DQS, and the tag data strobe line TDQS.

The SPD 140 may be a programmable read only memory device (e.g., an electrically erasable programmable read-only memory (EEPROM)). The SPD 140 may include initial information or device information DI of the nonvolatile memory module 100. In an embodiment, the SPD 140 may include the device information DI such as a module form, a module configuration, a storage capacity, a module type, and an execution environment that are associated with the nonvolatile memory module 100. When the user system 10 including the nonvolatile memory module 100 is booted, the processor 101 may read the device information DI from the SPD 140 and may recognize the nonvolatile memory module 100 based on the device information DI. The processor 101 may control the nonvolatile memory module 100 based on the device information DI read from the SPD 140.

Below, for descriptive convenience, it is assumed that the volatile memory 121 is a DRAM and that the nonvolatile memory 123 is a NAND flash memory. However, embodiments of the inventive concept are not limited thereto. For example, the volatile memory 121 may include another kind of random access memory, and the nonvolatile memory 123 may another kind of nonvolatile memory device. In an embodiment, the nonvolatile memory 123 may include a phase change memory.

In an embodiment, the volatile memory 121 may include a plurality of volatile memory chips, each of which is implemented with a separate chip, a separate package, etc. The volatile memory chips may be connected with the module controller 110 or the NVM controller 122 through different memory data lines or different tag data lines.

In an embodiment, the processor 101 may use the nonvolatile memory 123 of the nonvolatile memory module 100 as a main memory. That is, the processor 101 may recognize a storage space of the nonvolatile memory 123 as a main memory region. The volatile memory 121 may operate as a cache memory of the processor 101 and the nonvolatile memory 123. In an embodiment, the volatile memory 121 may be used as a write-back cache. That is, the module controller 110 may determine a cache hit or a cache miss in response to the module command/address CA from the processor 101 and may control the volatile memory 121 or the nonvolatile memory 123 based on the determination result.

In an embodiment, the cache hit may indicate the case that data corresponding to the module command/address CA received from the processor 101 is stored in the volatile memory 121. The cache miss may indicate the case that no data corresponding to the module command/address CA received from the processor 101 is stored in the volatile memory 121.

In an embodiment, the module controller 110 may determine whether the cache hit or the cache miss occurs, based on the tag “TAG”. The module controller 110 may determine whether the cache hit or the cache miss occurs, based on a result of comparing the module command/address CA from the processor 101 and the tag “TAG”.

In an embodiment, the tag “TAG” may include a part of an address that corresponds to data stored in the volatile memory 121. In an embodiment, the module controller 110 may exchange the tag “TAG” with the volatile memory 121 through the tag data line TDQ. In an embodiment, when data is written in the volatile memory 121, the tag “TAG” corresponding to the data may be written together with the data under control of the module controller 110.

In an embodiment, the volatile memory 121 and the nonvolatile memory 123 may have an n:l direct mapping relation. Here, “n” is a natural number. That is, the volatile memory 121 may be a direct mapped cache of the nonvolatile memory 123. For example, a first volatile storage region of the volatile memory 121 may correspond to first to n-th nonvolatile storage regions of the nonvolatile memory 123. In this case, the size of the first volatile storage area may be the same as that of each of the nonvolatile storage areas. In an embodiment, the first volatile storage area may further include an area for storing additional information (e.g., a tag, an ECC, dirty information, etc.).

In an embodiment, the volatile memory 121 and the nonvolatile memory 123 may have an n:k set associative mapping relation. Here, “k” is a natural number less than “n”. That is, the volatile memory 121 may be a set associative cache of the nonvolatile memory 123.

Although not shown in FIG. 2, the nonvolatile memory module 100 may further include a separate memory (not shown). The separate memory may store information, which is used in the NVM controller 122, such as data, programs, and software. For example, the separate memory may store information, which is managed by the NVM controller 122, such as a mapping table and a flash translation layer (FTL). Alternatively, the separate memory may be a buffer memory that temporarily stores data read from the nonvolatile memory 123 or data to be stored in the nonvolatile memory 123.

The nonvolatile memory 121 may include the first to fourth banks BANK1 to BANK4. The first to fourth banks BANK1 to BANK4 may perform write and read operations independently of each other. For example, the first to fourth banks BANK1 to BANK4 may correspond to banks that are defined by the specification of a double data rate dynamic random access memory (DDR DRAM).

The processor 101 may access the nonvolatile memory module 100 based on a dual in-line memory module (DIMM) or a nonvolatile dual in-line memory module (NVDIMM). The DIMM or NVDIMM may have command and address systems that are associated with the DDR DRAM. Alternatively, to enable the processor 101 to access the nonvolatile memory 123 based on the DIMM or NVDIMM, the nonvolatile memory 123 may have the address system that is organized based on the first to fourth banks BANK1 to BANK4, as defined by the specification of the DDR DRAM. For example, a storage space of the nonvolatile memory 123 may include a plurality of nonvolatile extended blocks NVM_BLK1 to NVM_BLKn. Each of the plurality of nonvolatile extended blocks NVM_BLK1 to NVM_BLKn may include the first to fourth regions BANK1 to BANK4.

The processor 101 may recognize the storage space of the nonvolatile memory 123 as a storage space of the nonvolatile memory module 100. The processor 101 may access the nonvolatile memory module 100 based on the DIMM or NVDIMM. However, an interface of the DIMM or NVDIMM is defined to coincide with the specification of the DDR DRAM. For example, the DIMM or NVDIMM provides an address system that distinguishes between the first to fourth banks BANK1 to BANK4 (or bank groups) of the volatile memory 121 and does not provide an address system that is able to distinguish between the plurality of nonvolatile extended blocks NVM_BLK1 to NVM_BLKn.

That is, in the case where the nonvolatile memory module 100 operates based on a conventional DIMM or NVDIMM, an issue may arise in that the processor 101 does not distinguish between the plurality of nonvolatile extended blocks NVM_BLK1 to NVM_BLKn during an access operation.

To solve such an issue, the nonvolatile memory module 100 according to an embodiment of the inventive concept provides a solution in which option signals or option lines are used as a nonvolatile extended block address (or an extended address) for distinguishing between the plurality of nonvolatile extended blocks NVM_BLK1 to NVM_BLKn, in the address system of the DIMM or NVDIMM.

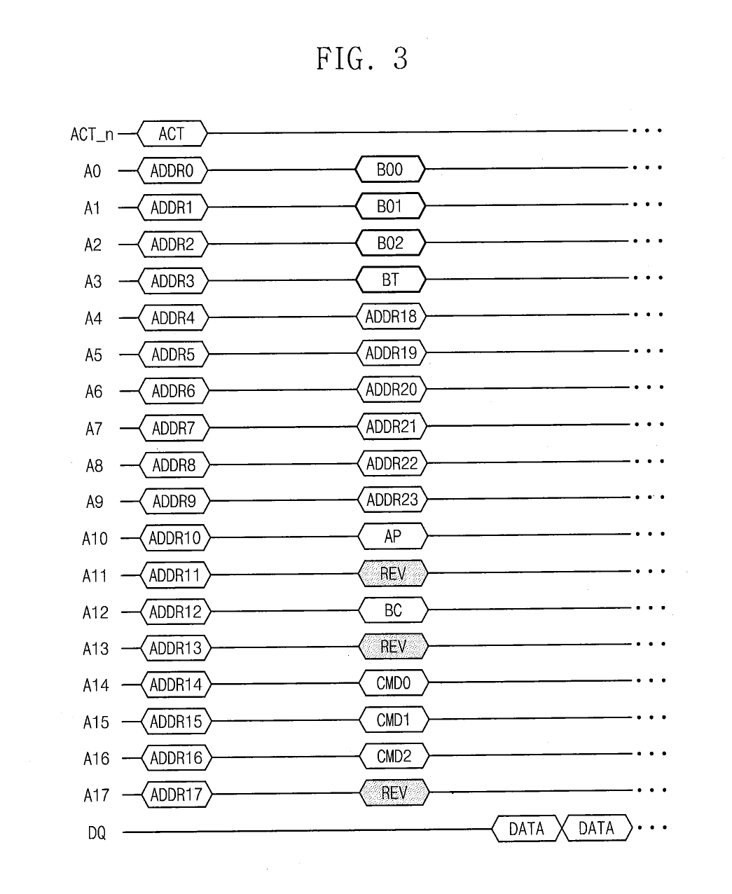

FIG. 3 is a timing diagram illustrating a process in which a command and an address are sent to a nonvolatile memory module based on the DIMM or NVDIMM. Signals of an active command input line ACT_n and an address lines A0 to A17 transferred to the module controller 110 and signals of data lines DQ transferred to the data buffer 130 are illustrated in FIGS. 2 and 3. For descriptive convenience, a bank address for distinguishing between the first to fourth banks BANK1 to BANK4 is not illustrated in FIG. 3.

When an active command (or an active signal) ACT is received through the active command input line ACT_n, 0th to 17th addresses (e.g., address signals) ADDR0 to ADDR17 may be provided to the module controller 110 through 0th to 17th address lines A0 to A17. In an embodiment, the 1st to 17th addresses ADDR1 to ADDR17 may constitute a row address for selecting a row of a selected bank in the volatile memory 121 or a row of a selected bank of a selected nonvolatile extended block in the nonvolatile memory 123. The active command ACT may indicate that signals received through the 1st to 17th address lines A0 to A17 are a row address.

If a predefined time elapses from an input of the active command ACT, next signals may be received through the 0th to 17th address lines A0 to A17. Signals that are received through the 14th to 16th address lines A14 to A16 may be 0th to 2nd commands CMDO to CMD2. Signals that are received through the 4th to 9th address lines A4 to A9 may be 18th to 23th addresses ADDR18 to ADDR23. For example, the 18th to 23th addresses ADDR18 to ADDR23 may constitute a column address for selecting a row of a selected bank in the volatile memory 121 or a column of a selected bank of a selected nonvolatile extended block in the nonvolatile memory 123.

Signals that are received through the 0th to 2nd address lines A0 to A2 may indicate a burst order BO0 to BO2. For example, the burst order BO0 to BO2 may indicate the order of pieces of data when receiving or outputting pieces of data according to a predefined or separately determined burst length. A signal that is received through the third address line A3 may indicate a burst type BT. The burst type BT may include “sequential” or “interleaved”. The 12th address line A12 may indicate burst chopping BC. The burst chopping BC may indicate that a portion of the predefined or separately determined burst length is not used. The 10th address line A10 may indicate auto precharge AP.

The burst order BO0 to BO2, the burst type BT, the auto precharge AP, and the burst chopping BC are option information for setting an operation of the nonvolatile memory module 100, not an address used to distinguish between locations of a storage space. The nonvolatile memory module 100 may recognize at least some of signals received through the address lines A0 to A3, A10, and A12 together with a command CMD0 to CMD2 as the nonvolatile extended block address for distinguishing between the nonvolatile extended blocks NVM BLK1 to

NVM BLKn.

When accessing the nonvolatile memory module 100, the processor 101 may send the nonvolatile extended block address through at least some of the address lines A0 to A3, A10, and A12 at timing when the command CMD0 to CMD2 is sent.

When the 0th to 2nd address lines A0 to A2 are used to send the nonvolatile extended block address, the processor 101 fails to send the burst order BO0 to BO2 to the nonvolatile memory module 100 and the nonvolatile memory module 100 fails to receive the burst order BO0 to BO2. In this case, the nonvolatile memory module 100 and the processor 101 may communicate with each other based on the predefined or separately determined burst order. For example, information about the burst order may be stored in the SPD 140 and may be detected by the processor 101 when the processor 101 and the nonvolatile memory module 100 are initialized. The processor 101 may communicate with the nonvolatile memory module 100 based on the detected burst order.

When the third address line A3 is used to send the nonvolatile extended block address, the processor 101 fails to send the burst type BT to the nonvolatile memory module 100 and the nonvolatile memory module 100 fails to receive the burst type BT. In this case, the nonvolatile memory module 100 and the processor 101 may communicate with each other based on a predefined or separately determined burst type. For example, information about the burst order may be stored in the SPD 140 and may be detected by the processor 101 when the processor 101 and the nonvolatile memory module 100 are initialized. The processor 101 may communicate with the nonvolatile memory module 100 based on the detected burst type.

When the 12th address line A12 is used to send the nonvolatile extended block address, the processor 101 fails to send the burst chopping BC to the nonvolatile memory module 100 and the nonvolatile memory module 100 fails to receive the burst chopping BC. In this case, the nonvolatile memory module 100 and the processor 101 may communicate with each other based on a predefined or separately determined burst chopping. For example, information about the burst chopping may be stored in the SPD 140 and may be detected by the processor 101 when the processor 101 and the nonvolatile memory module 100 are initialized. The processor 101 may communicate with the nonvolatile memory module 100 based on the detected burst chopping.

When the tenth address line A10 is used to send the nonvolatile extended block address, the processor 101 fails to send the auto precharge AP to the nonvolatile memory module 100 and the nonvolatile memory module 100 fails to receive the auto precharge AP. In this case, the nonvolatile memory module 100 may determine whether to perform the auto precharge, based on predefined or separately determined information.

Continuing to refer to FIG. 3, when the command CMD0 to CMD2 is received, the address lines A11, A13, and A17 are reserved lines REV. Accordingly, the reserved lines REV may be used to send the nonvolatile extended block address.

Data may be conveyed through the data lines DQ when a row address associated with the volatile memory 121 and the nonvolatile memory 123 is received at first timing when the active command ACT is sent and a column address associated with the volatile memory 121 and the nonvolatile memory 123 and a nonvolatile extended block address associated with the nonvolatile memory 123 are sent at second timing when the command CMD0 to CMD2 is received.

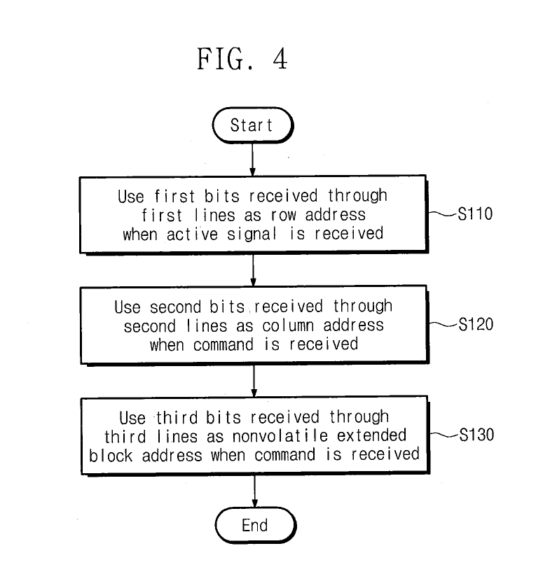

FIG. 4 is a flowchart illustrating an operating method of a nonvolatile memory module according to an embodiment of the inventive concept. Referring to FIGS. 2 to 4, in operation S110, when the active command ACT is received, the module controller 110 may use first bits received through first lines as a row address. For example, the first lines may be the address lines A0 to A17.

In operation S120, when the command CMD0 to CMD2 is received, the module controller 110 may use second bits received through second lines as a column address. For example, the second lines may be the address lines A4 to A9.

In operation S130, when the command CMD0 to CMD2 is received, the module controller 110 may use third bits received through third lines as a nonvolatile extended block address. For example, the third lines may include at least some of the address lines A0 to A3, A10, and A12. Furthermore, the third lines may include at least some of the address lines A11, A13, and A17.

The embodiments of the inventive concept are described with reference to address lines. However, the term “address lines” are only names set to distinguish lines associated with the inventive concept from other lines. Therefore, embodiments of the inventive concept are not limited thereto. For example, as described with reference to FIG. 3, the command CMD0 to CMD2 and option signals BO0 to BO2, BC, BT, and AP that are not an address even though the term “address line” is used may be conveyed through “address lines”.

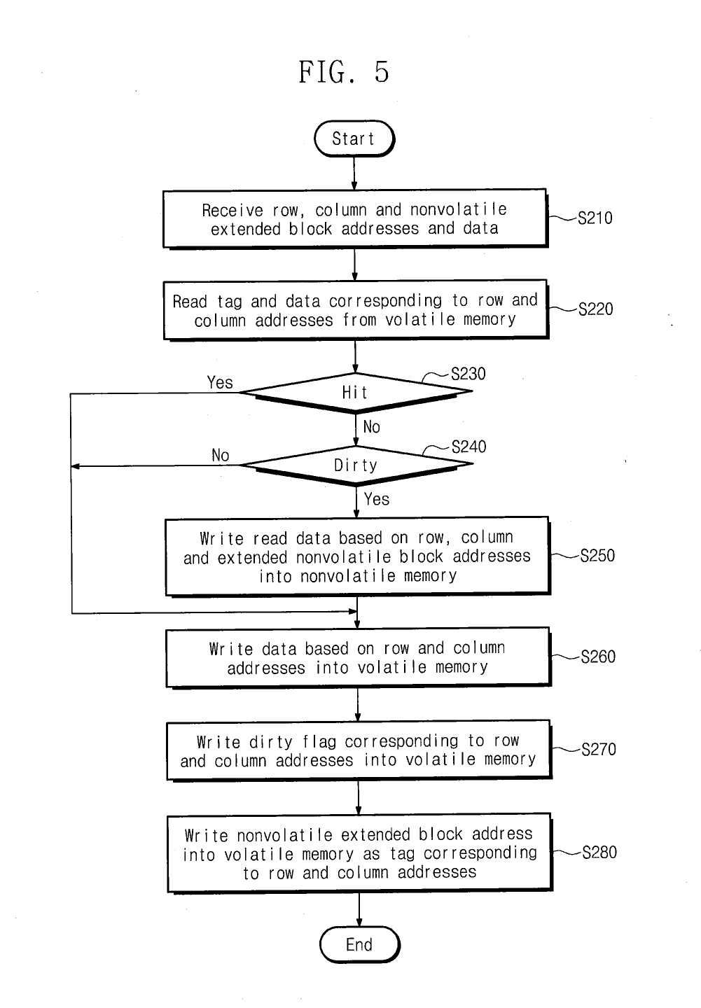

FIG. 5 is a flowchart illustrating a method in which the nonvolatile memory module writes data under control of the processor. Referring to FIGS. 1, 2, and 5, in operation S210, the nonvolatile memory module 100 may receive a row address, a column address, a nonvolatile extended block address, and data from the processor 101. The row address, the column address, and the nonvolatile extended block address may be sent to the module controller 110 as a module command/address CA. The data may be set to the data buffer 130 through the data lines DQ. The module controller 110 may generate the VM command/address CA_v and may send the VM command/address CA_v to the volatile memory 121 and the NVM controller 122. The module controller 110 may generate the NVM command/address CA_n and may send the NVM command/address CA_n to the NVM controller 122.

In operation S220, the module controller 110 or the NVM controller 122 may read a tag corresponding to the row and column addresses from the volatile memory 121. For example, the module controller 110 may send the VM command/address CA_v for requesting a read operation to the volatile memory 121. For example, the volatile memory 121 may load the tag “TAG” on the tag data line TDQ and may load memory data on the memory data line MDQ. The module controller 110 or the NVM controller 122 may receive the tag “TAG” loaded on the tag data line TDQ and the memory data loaded on the memory data line MDQ.

In operation S230, the module controller 110 or the NVM controller 122 may determine whether a hit or miss is generated. For example, the hit may be determined when the nonvolatile extended block address received from the processor 101 is the same as the tag read from the volatile memory 121. If the hit is determined, operations S240 and S250 are omitted, and operation S260 is performed.

In operation S230, the miss may be determined when the nonvolatile extended block address received from the processor 101 is different from the tag read from the volatile memory 121. If the miss is determined, operation S240 is performed.

In operation S240, the module controller 110 or the NVM controller 122 determines whether a dirty flag is written in a storage space of the volatile memory 121 corresponding to the row and column addresses. If the dirty flag is not written in the storage space, operation S250 is omitted, and operation S260 is performed.

If that the dirty flag is written in the storage space is determined in operation S240, the module controller 110 or the NVM controller 122 may perform operation S250. In operation S250, the module controller 110 or the NVM controller 122 may write data read from the volatile memory 121 in the nonvolatile memory 123 based on the row address, the column address, and the nonvolatile extended block address. For example, the module controller 110 may provide the NVM controller 122 with the NVM command/address CA_n for requesting to write data loaded on the memory data line MDQ. Afterwards, operation S260 is performed.

In operation S260, the module controller 110 or the NVM controller 122 may write data in the volatile memory 121 based on the row and column addresses. The module controller 110 may control the data buffer 130 to load data received through the data lines DQ on the memory data line MDQ. The module controller 110 may send the VM command/address CA_v for requesting a write operation to the volatile memory 121.

In operation S270, the module controller 110 or the NVM controller 122 may write the dirty flag in a storage space of the volatile memory 121 corresponding to the row and column addresses. The dirty flag may be written in the volatile memory 121 together with the tag “TAG” through the tag data line TDQ or together with data through the memory data line MDQ. For example, the module controller 110 or the NVM controller 122 may load information to be written as the dirty flag on the tag data line TDQ or the memory data line MDQ. The module controller 110 may provide the volatile memory 121 with the VM command/address CA_v for requesting to write data loaded on the tag data line TDQ or the memory data line MDQ. For example, the dirty flag and data may be written together. For example, operations S240 and S250 may be performed at the same time.

In operation S280, the module controller 110 or the NVM controller 122 may write the nonvolatile extended block address as the tag “TAG” in the volatile memory 121 corresponding to the row and column addresses. For example, the module controller 110 or the NVM controller 122 may load the nonvolatile extended block address on the tag data line TDQ. The module controller 110 may provide the volatile memory 121 with the VM command/address CA_v for requesting to write data loaded on the tag data line TDQ. For example, the tag “TAG” may be written together with the dirty flag or data. For example, operation S280 and operations S240 and S250 may be performed at the same time.

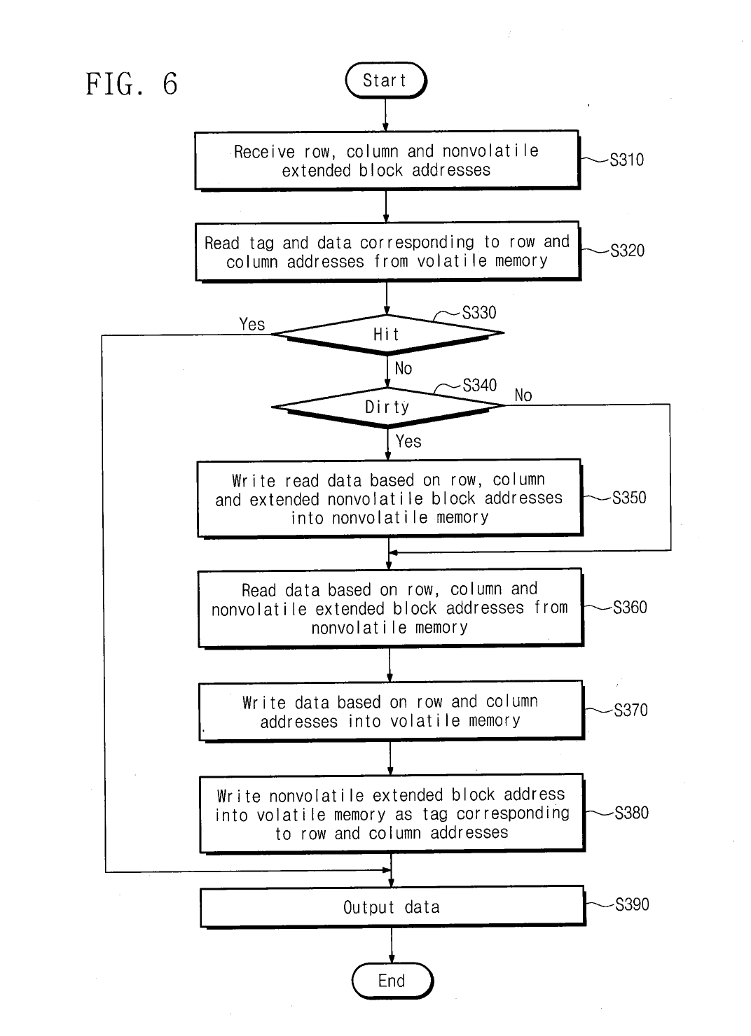

FIG. 6 is a flowchart illustrating a method in which the nonvolatile memory module reads data under control of the processor. Referring to FIGS. 1, 2, and 6, in operation S310, the nonvolatile memory module 100 may receive a row address, a column address, a nonvolatile extended block address, and data from the processor 101. The row address, the column address, and the nonvolatile extended block address may be sent to the module controller 110 as a module command/address CA. The module controller 110 may generate the VM command/address CA_v and may send the VM command/address CA_v to the volatile memory 121 and the NVM controller 122. The module controller 110 may generate the NVM command/address CA_n and may send the NVM command/address CA_n to the NVM controller 122.

In operation S320, the module controller 110 or the NVM controller 122 may read a tag corresponding to the row and column addresses from the volatile memory 121. For example, the module controller 110 may send the VM command/address CA_v for requesting a read operation to the volatile memory 121. For example, the volatile memory 121 may load the tag “TAG” on the tag data line TDQ and may load memory data on the memory data line MDQ. The module controller 110 or the NVM controller 122 may receive the tag “TAG” loaded on the tag data line TDQ and the memory data loaded on the memory data line MDQ.

In operation S330, the module controller 110 or the NVM controller 122 may determine whether a hit or miss is generated. For example, the hit may be determined when the nonvolatile extended block address received from the processor 101 is the same as the tag read from the volatile memory 121. If the hit is determined, operations 5340 and 5380 are omitted, and operation S390 is performed.

In operation S330, the miss may be determined when the nonvolatile extended block address received from the processor 101 is different from the tag read from the volatile memory 121. If the miss is determined, operation S340 is performed.

In operation S340, the module controller 110 or the NVM controller 122 determines whether a dirty flag is written in a storage space of the volatile memory 121 corresponding to the row and column addresses. If the dirty flag is not written in the storage space, operation S350 is omitted, and operation S360 is performed.

If that the dirty flag is written in the storage space is determined in operation S340, the module controller 110 or the NVM controller 122 may perform operation S350. In operation S350, the module controller 110 or the NVM controller 122 may write data read from the volatile memory 121 in the nonvolatile memory 123 based on the row address, the column address, and the nonvolatile extended block address. For example, the module controller 110 may provide the NVM controller 122 with the NVM command/address CA_n for requesting to write data loaded on the memory data line MDQ. Afterwards, operation S260 is performed.

In operation S360, the module controller 110 or the NVM controller 122 may read data from the nonvolatile memory 123 based on the row address, the column address, and the nonvolatile extended block address. For example, the module controller 110 may provide the NVM controller 122 with the NVM command/address CA n so as to read data and load the read data on the memory data line MDQ.

In operation S370, the module controller 110 or the NVM controller 122 may write data in the volatile memory 121 based on the row and column addresses. For example, the module controller 110 may provide the volatile memory 121 with the VM command/address CA_v so as to write data loaded on the memory data line MDQ.

In operation S380, the module controller 110 or the NVM controller 122 may write the nonvolatile extended block address as the tag “TAG” in the volatile memory 121 corresponding to the row and column addresses. For example, the module controller 110 or the NVM controller 122 may load the nonvolatile extended block address on the tag data line TDQ. The module controller 110 may provide the volatile memory 121 with the VM command/address CA_v for requesting to write data loaded on the tag data line TDQ. For example, the tag “TAG” may be written together with data. For example, operation S380 and operation S370 may be performed at the same time.

In step S390, the nonvolatile memory module A200 may output the data. For example, the module controller 110 may control the data buffer 130 so as to output data loaded on the memory data line MDQ.

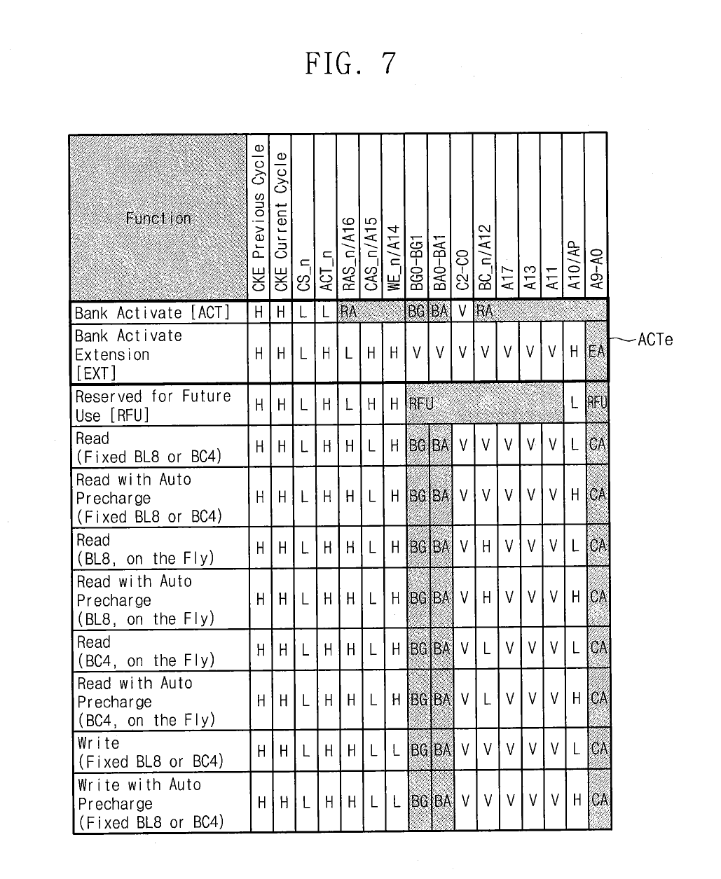

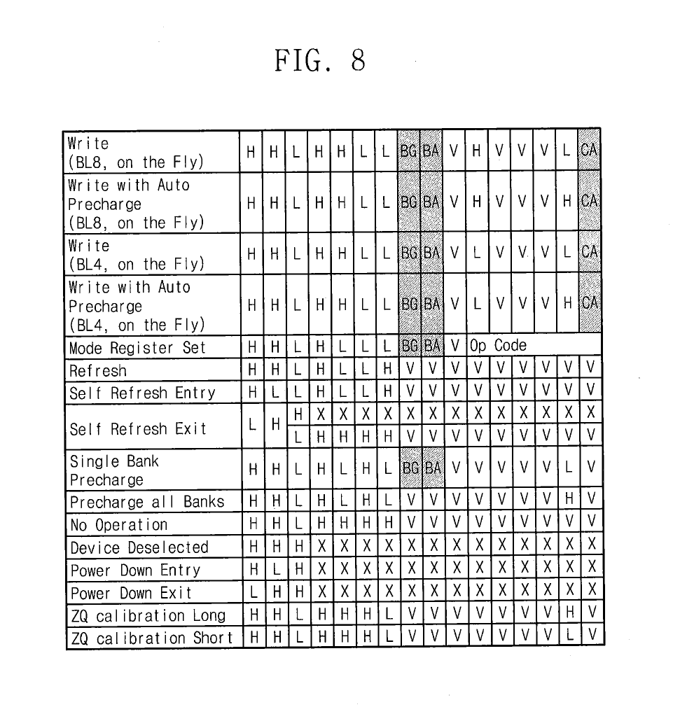

FIGS. 7 and 8 illustrate examples in which an extended address (or a nonvolatile extended block address) is sent according to applications of the inventive concept. Kinds of commands to be sent to the nonvolatile memory module 100 and a module command/address CA according to the commands are illustrated in FIGS. 7 and 8.

Referring to FIGS. 2, 7, and 8, the module command/address CA may be sent through a clock enable signal CKE, a chip select enable signal CS_n, an active command input line ACT_n, command input lines RAS_n/A16, CAS_n/A15, and WE_n/A14, bank group input lines BG0 and BG1, bank address input lines BA0 and BA1, chip identifier lines C0 to C2, a burst chop signal line BC_n/A12, address lines A11, A13, and A17, an auto precharge signal line A10/AP, and address lines A0 to A9.

The clock enable signal line CKE may send an internal clock and a clock enable signal for controlling activation and inactivation of an input buffer and an output driver in the nonvolatile memory module 100 or the volatile memory 121. Levels of a previous cycle and a current cycle of the clock enable signal line CKE may be used to determine a kind of command included in the module command/address CA.

A chip select signal sent through the chip select signal line CS_n may indicate whether the module command/address CA is valid or invalid in the nonvolatile memory module 100 or the volatile memory 121.

The active command input line ACT_n may transmit the active command ACT, and the active command ACT may be recognized as an active command.

Each of the command input lines RAS_n/A16, CAS_n/A15, and WE_n/A14 is used for multi-purpose. When the active command ACT is activated, the command input lines RAS_n/A16, CAS_n/A15, and WE_n/A14 may transmit a row address RA corresponding to the address lines A14 to A16. When the active command ACT is inactivated, each of the command input lines RAS_n/A16, CAS_n/A15, and WE_n/A14 may transmit a command.

The bank group input lines BG0 and BG1 may transmit a bank group signal BG indicating a bank group to be activated.

The bank group input lines BG0 and BG1 may transmit a bank address BA indicating a bank address to be activated.

The chip identifier lines C0 to C2 may transmit an identifier for selecting each slice in a three-dimensional structure having the slices stacked on the basis of a through silicon via (TSV).

The burst chop signal line BC_n/A12 is used for multi-purpose. When the active command ACT is activated, the burst chop signal line BC_n/A12 may transmit a row address RA corresponding to the address line A12. When the active command ACT is inactivated and a command included in the module command/address indicates a read operation, the burst chop signal line BC_n/A12 may transmit the burst chopping signal BC indicating whether to perform burst chopping.

The address lines A11, A13, and A17 are used for multi-purpose. When the active command ACT is activated, each of the address lines A11, A13, and A17 may transmit a row address RA. When the active command ACT is inactivated, each of the address lines A11, A13, and A17 may not transmit a valid signal. For example, the address lines A11, A13, and A17 may be reserved lines.

The auto precharge signal line A10/AP is used for multi-purpose. When the active command ACT is inactivated, the auto precharge signal line A10/AP may transmit a row address RA corresponding to the address line A10. When the active command ACT is inactivated and signals (e.g., a command) transmitted through the command input lines RAS_n/A16, CAS_n/A15, and WE_n/A14 have a predefined pattern (e.g., a reserved pattern), the auto precharge signal line A10/AP may transmit the auto precharge signal AP indicating whether to perform auto precharge. Furthermore, when the active command ACT is inactivated and signals (e.g., a command) transmitted through the command input lines RAS_n/A16, CAS_n/A15, and WE_n/A14 have a predefined pattern (e.g., a reserved pattern), the auto precharge signal line A10/AP may transmit an activation extension command EXT.

The address lines A0 to A9 are used for multi-purpose. When the active command ACT is activated, each of the address lines A0 to A9 may transmit a row address RA. When the active command ACT is inactivated and the command input lines RAS_n/A16, CAS_n/A15, and WE_n/A14 do not have the reserved pattern, each of the command input lines RAS_n/A16, CAS_n/A15, and WE_n/A14 may transmit a column address CA. When the active command ACT is inactivated and the command input lines RAS_n/A16, CAS_n/A15, and WE_n/A14 have the reserved pattern, each of the command input lines RAS_n/A16, CAS_n/A15 when the activation extension command EXT, and the address lines A0 to A9 may transmit an extended address EA.

As illustrated in FIGS. 7 and 8, a command and an address included in the module command/address CA may be respectively recognized according to the clock enable signal CKE, the chip select enable signal CS_n, the active command input line ACT_n, the command input lines RAS_n/A16, CAS_n/A15, and WE_n/A14, the bank group input lines BG0 and BG1, the bank address input lines BA0 and BA1, the chip identifier lines C0 to C2, the burst chop signal line BC_n/A12, the address lines A11, A13, and A17, the auto precharge signal line A10/AP, and the address lines A0 to A9 included in the module command/address CA.

For example, a command included in the module command/address CA may include a bank active command ACT (or the active command), a bank activation extension command EXT (or an active extended command), reservation for feature use RFU, read having a burst length of fixed “BL8” or burst chopping of “BC4” (Read (Fixed BL8 or BC4)), read having a burst length of fixed “BL8” or burst chopping of “BC4” and accompanying auto precharge (Read with Auto Precharge (Fixed BL8 or BC4)), read having a burst length of “BL8” as a default value and adjusted on the fly (Read (BL8, on the fly)), read having a burst length of “BL8” as a default value, adjusted on the fly, and accompanying auto precharge (Read with Auto Precharge (BL8, on the fly)), read having burst chopping of “BC4” as a default value and adjusted on the fly (Read (BC4, on the fly)), and read having burst chopping of “BC4” as a default value, adjusted on the fly, and accompanying auto precharge (Read with Auto Precharge (BC4, on the fly)).

For example, a command included in the module command/address CA may include write having a burst length of fixed “BL8” or burst chopping of “BC4” (Write (Fixed BL8 or BC4)), write having a burst length of fixed “BL8” or burst chopping of “BC4” and accompanying auto precharge (Write with Auto Precharge (Fixed BL8 or BC4)), write having a burst length of “BL8” as a default value and adjusted on the fly (Write (BL8, on the fly)), write having a burst length of “BL8” as a default value, adjusted on the fly, and accompanying auto precharge (Write with Auto Precharge (BL8, on the fly)), write having burst chopping of “BC4” as a default value and adjusted on the fly (Write (BC4, on the fly)), and write having burst chopping of “BC4” as a default value, adjusted on the fly, and accompanying auto precharge (Write with Auto Precharge (BC4, on the fly)).

The command included in the module command/address CA may further include mode register set, refresh, self-refresh entry, self-refresh exit, single bank precharge, precharge all Banks, no operation, device deselected, power down entry, power down exit), ZQ calibration long, and ZQ calibration short.

In FIGS. 7 and 8, “H” indicates a high level, and “L” indicates a low level. “V” indicates a specific level defined as one of “H” and “L”. “X” indicates a thing that is defined or not defined (e.g., floating) or is not relevant. “RA” indicates that a row address RA is sent. “CA” indicates that a column address CA is sent. “RFU” indicates reservation for feature use. Here, the term “reserved” is used on the basis of a current state and is defined and used for another use after this application is filed. “BG” indicates that a bank group signal BG is sent. “BA” indicates that a bank address BA is sent. “EA” indicates that an extended address EA is sent. “Op Code” indicates that an operation code is sent.

In FIGS. 7 and 8, the bank activation extension command EXT is defined. The bank activation extension command EXT may be recognized when a signal of the clock enable signal line CKE is at a high level “H” in previous and current cycles, a signal of the chip enable signal line CS_n is at a low level “L”, a signal of the active command input line ACT_n is at a high level “H”, signals of the command input lines RAS_n/A16, CAS_n/A15, and WE_n/A14 are at a low level “L”, a high level “H”, and a high level “H”, respectively, and a signal of the auto precharge signal line A10/AP is at a high level “H”. The extended address EA may be sent through the address lines A0 to A9 together with the bank activation extension command EXT.

In an embodiment, the bank activation extension command EXT may constitute an extended active command ACTe together with the bank active command ACT. In an embodiment, the bank active command ACT and the bank activation extension command EXT may be consecutively sent, and another command may not be sent between the bank active command ACT and the bank activation extension command EXT. That is, the extended active command ACTe including the bank active command ACT and the bank activation extension command EXT is sent, the row address RA and the extended address EA are sent to the nonvolatile memory module 100.

In the embodiment described with reference to FIGS. 7 and 8, the bank activation extension command EXT is recognized when the command input lines RAS_n/A16, CAS_n/A15, and WE_n/A14 form a reserved pattern, for example, a low level “L”, a high level “H”, and a high level “H” and a signal of the auto precharge signal line A10/AP is at a high level “H”. However, the bank activation extension command EXT may be recognized when a signal of the auto precharge signal line A10/AP is at a low level “L”. In this case, a command in which a signal of the auto precharge signal line A10/AP is at a high level “H” may be a reserved command RFU for feature use. In another embodiment, the bank activation extension command EXT is recognized regardless of a signal of the auto precharge signal line A10/AP when the command input lines RAS_n/A16, CAS_n/A15, and WE_n/A14 form a reserved pattern, for example, a low level “L”, a high level “H”, and a high level “H”.

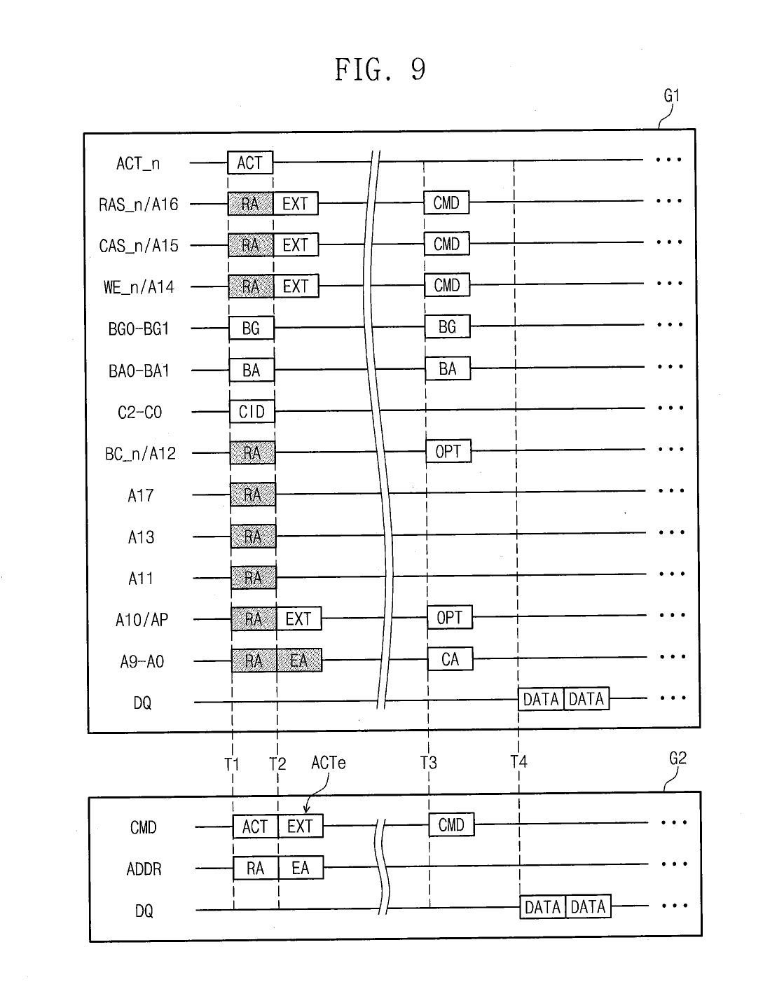

FIG. 9 is a timing diagram illustrating an application of a process in which a command and an address are sent to the nonvolatile memory module based on the DIMM or NVDIMM. In FIG. 9, a first graph G1 shows signals transmitted through signal lines. A second graph G2 shows a command CMD, an address ADDR, and data DQ that are briefly expressed by using signals transmitted through signal lines.

Referring to FIGS. 2 and 7 to 9, at T1, the active command ACT is transmitted through the active command input line ACT_n as a command CMD. Furthermore, a row address RA is transmitted as an address ADDR through the command input lines RAS_n/A16, CAS_n/A15, and WE_n/A14, the burst chop signal line BC_n/A12, the address lines A11, A13, and A17, the auto precharge signal line A10/AP, and the address lines A0 to A9. The bank group signal BG, the bank address BA, and the chip identifier CID are transmitted through the bank group input lines BG0 and BG1, the bank address input lines BA0 and BA1, and the chip identifier lines C0 to C2, respectively.

At T2, the bank activation extension command EXT is transmitted as a command CMD through the command input lines RAS_n/A16, CAS_n/A15, and WE_n/A14 and the auto precharge signal line A10/AP. The extended address EA are transmitted through the address lines A0 to A9 as an address ADDR.

The active command ACT and the bank activation extension command EXT may be continuously transmitted. The active command ACT is transmitted together with the row address RA, and the extended active command EXT is transmitted together with the extended address EA. The active command ACT and the extended active command EXT may constitute the extended active command ACTe.

After the nonvolatile memory module 100 or the volatile memory 121 completely activates an access target, that is, a storage space in response to the extended active command ACTe, at T3, a command CMD is transmitted through the command input lines RAS_n/A16, CAS_n/A15, and WE_n/A14. The command CMD may indicate one of the remaining commands of the commands described with reference to FIGS. 7 and 8 except for the active command ACT and the extended active command EXT. The column address CA is transmitted through the address lines A0 to A9 as an address ADDR. The bank group signal BG and the bank address BA are transmitted through the bank group input lines BG0 and BG1 and the bank address input lines BA0 and BA1, respectively. Signals may be transmitted through the burst chop signal line BC_n/A12 and the auto precharge signal line A10/AP as an option OPT.

At T4, Data may be exchanged in response to the command CMD that is transmitted at T3.

As described above, the nonvolatile memory module 100 according to an embodiment of the inventive concept may be configured to identify the activation extension command EXT based on signals of the command input lines RAS_n/A16, CAS_n/A15, and WE_n/A14 or signals of the command input lines RAS_n/A16, CAS_n/A15, and WE_n/A14 and an additional line, for example, the auto precharge signal line A10/AP. The nonvolatile memory module 100 may recognize the extended address EA based on the activation extension command EXT.

The row address RA received together with the active command ACT and the column address CA received together with the command CMD may be applied in common to the volatile memory 121 and the nonvolatile memory 123, and the extended address received together with the activation extension command EXT may not be applied to the volatile memory 121 and may be applied to the nonvolatile memory 123. In an embodiment, as described with reference to FIGS. 5 and 6, the extended address EA may be used as a tag.

In an embodiment, whether the nonvolatile memory module 100 supports the activation extension command EXT may be stored in the SPD 140. The processor 101 (refer to FIG. 1) may determine whether the nonvolatile memory module 100 supports the activation extension command EXT, based on information read from the SPD 140. If the nonvolatile memory module 100 supports the activation extension command EXT, as described with reference to FIGS. 7 to 9, the processor 101 may send the extended active command ACTe to the nonvolatile memory module 100. If the nonvolatile memory module 100 does not support the extended active command ACTe, as described with reference to FIGS. 3 and 4, the processor 101 may send the nonvolatile extended block address together with the active command ACT.

In the case where the processor 101 sends the extended active command ACTe, the nonvolatile memory module 100 or the module controller 110 may obtain the row address RA from the active command ACT included in the extended active command ACTe and may obtain the extended address EA from the activation extension command EXT included in the extended active command ACTe.

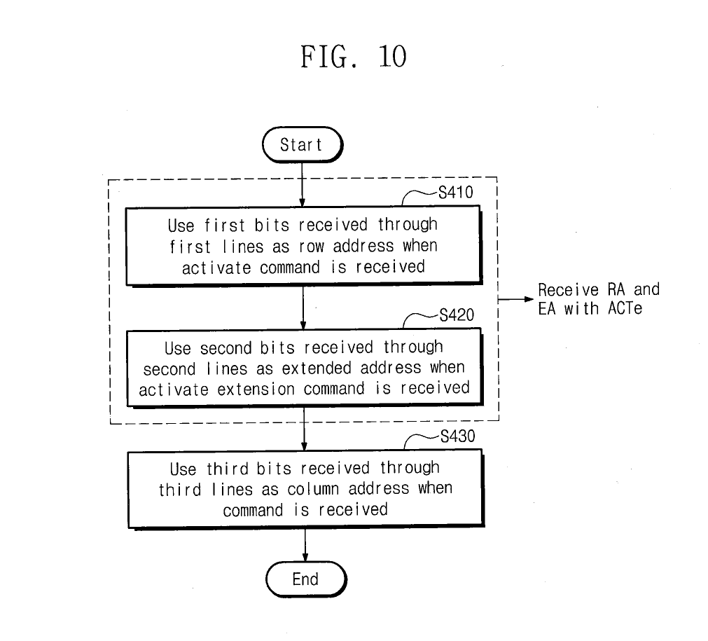

FIG. 10 is a flowchart illustrating a method in which the nonvolatile memory module 100 obtains the row address RA, the extended address EA, and the column address CA from the extended active command ACTe. Referring to FIGS. 2 and 7 to 10, in operation S410, the nonvolatile memory module 100 uses first bits, which are received through first lines when the active command ACT is received, as the row address RA. For example, the active command ACT may be received through the active command input line ACT_n. For example, the first lines may include the command input lines RAS_n/A16, CAS_n/A15, and WE_n/A14, the burst chop signal line BC_n/A12, the address lines A11, A13, and A17, the auto precharge signal line A10/AP, and the address lines A0 to A9.

In operation S420, the nonvolatile memory module 100 uses second bits, which are received through second lines when the activation extension command EXT is received, as the extended address EA. For example, the activation extension command EXT may be received through the command input lines RAS_n/A16, CAS_n/A15, and WE_n/A14 or through the command input lines RAS_n/A16, CAS_n/A15, and WE_n/A14 and an additional line, for example, the auto precharge signal line A10/AP. The second lines may be the address lines A0 to A9.

In operations S410 and S420, the row address RA and the extended address EA are received together with the extended active command ACTe.

In operation S430, the nonvolatile memory module 100 uses third bits, which are received through third lines when the command CMD is received, as the column address CA. The command CMD may be received through the command input lines RAS_n/A16, CAS_n/A15, and WE_n/A14. The third lines may be the address lines A0 to A9.

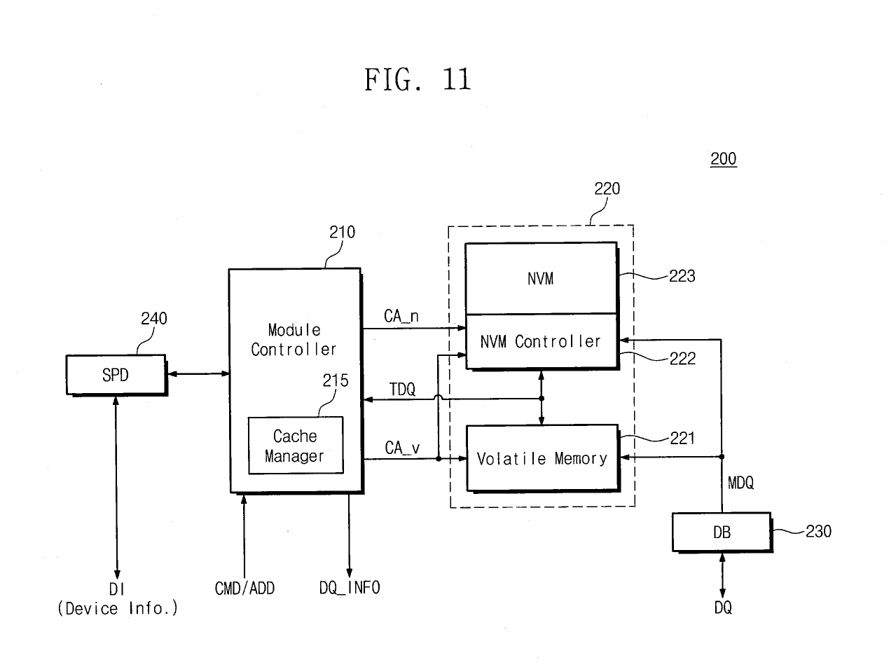

FIG. 11 is a block diagram illustrating the nonvolatile memory module of FIG. 1 according to another embodiment of the inventive concept. Referring to FIGS. 1 and 11, the nonvolatile memory module 200 includes a module controller 210 (or a RAM control device), a heterogeneous memory device 220, a data buffer (DB) 230, and a SPD 240.

The module controller 210 may operate similar with the module controller 110.

The heterogeneous memory device 220 may include the volatile memory 221, the NVM controller 222, and the nonvolatile memory 223. The volatile memory 221 may operate in response to the VM command/address CA_v from the module controller 210. The volatile memory 221 may output data and a tag “TAG” through a memory data line MDQ and a tag data line TDQ respectively in response to the VM command/address CA_v. The volatile memory 221 may write data and a tag respectively received through the memory data line MDQ and the tag data line TDQ based on the VM command/address CA_v.

The NVM controller 222 may operate in response to the NVM command/address CA_n from the module controller 210. For example, on the basis of the NVM command/address CA_n from the module controller 210, the NVM controller 222 may program data received through the memory data line MDQ in the nonvolatile memory 223 or may output data programmed in the nonvolatile memory 223 through the memory data line MDQ.

The NVM controller 222 may operate similar with the NVM controller 122.

In an embodiment, the volatile memory 221 and the NVM controller 222 may share the same memory data line MDQ.

In an embodiment, the volatile memory 221 and the module controller 210 may share the tag data line TDQ. Alternatively, the volatile memory 221, the NVM controller 222, and the module controller 210 may share the tag data line TDQ. The NVM controller 222 may output a tag “TAG” through the tag data line TDQ.

The data buffer 230 may operate or configured similar with the data buffer 130 in association with the memory data line MDQ and the data line DQ.

The SPD 240 may operate or configured similar with the SPD 140.

In an embodiment, the cache manager 215 may assign and manage transaction identifications TID with respect to cache-missed addresses. Firstly, the cache miss may be generated during a read operation associated with a first address ADD_1. In this case, the cache manager 215 may assign a first transaction identification TID1 to the cache-missed first address ADD 1. Secondly, the cache hit may be generated during a read operation associated with a second address ADD 2. In this case, the cache manager 215 may not perform a separate operation. Thirdly, the cache miss may be generated during a read operation associated with a third address ADD_3. In this case, the cache manager 215 may assign a second transaction identification TID2 to the cache-missed third address ADD_3. Likewise, the cache hit may be generated during each of read operations associated with fourth and fifth addresses ADD_4 and ADDS; when the cache miss is generated during a read operation associated with a sixth address ADD_6, the cache manager 215 may assign a third transaction identification TID3 to the sixth address ADD_6. Each of the first to third transaction identifications TID1, TID2, and TID3 may be implemented to be increased monotonically.

That is, the cache manager 215 may manage cache-missed addresses such that transact identifications TID are respectively assigned to the cache-missed addresses whenever the cache miss is generated. In this case, the transaction identification may increase monotonically. The transaction identifications may be provided to the processor 101 together with validity information DQ_INFO indicating whether the cache hit is generated.

In an embodiment, the tag “TAG” may include a portion of an address that corresponds to data stored in the volatile memory 221. In an embodiment, the module controller 210 may exchange the tag “TAG” with the volatile memory 221 through the tag data line TDQ. In an embodiment, when data is written in the volatile memory 221, the tag “TAG” corresponding to the data may be written in the volatile memory 221 together with the data under control of the module controller 210.

In detail, read-requested data may be output through the data line DQ after a fixed latency RL in response to a read command from the processor 101. The module controller 210 may send the validity information DQ_INFO of data output through the data line DQ to the processor 101 based on a result of a cache check operation. The validity information DQ_INFO may include validity and a transaction identification TID associated with data output through the data line DQ. The processor 101 may be provided with cache-missed data, which is capable of being output at a point in time after the latency RL, with reference to the validity information DQ_INFO. That is, the processor 101 may again request the cache-missed data with reference to the transaction identification TID.

In an embodiment, the volatile memory 221 and the nonvolatile memory 223 may have a n:l direct mapping relation (“n” being a natural number). That is, the volatile memory 221 may be a direct mapped cache of the nonvolatile memory 223. For example, a first volatile storage region of the volatile memory 221 may correspond to first to n-th nonvolatile storage regions of the nonvolatile memory 223. In this case, the size of the first volatile storage region may be the same as that of each of the first to n-th nonvolatile storage regions. In an embodiment, the first volatile storage region may further include a region for storing additional information (e.g., a tag, an ECC, dirty information, etc.).

Although not shown in FIG. 11, the nonvolatile memory module 200 may further include a separate memory (not shown). The separate memory may store information used in the NVM controller 222, such as data, programs, and software. For example, the separate memory may store information managed by the NVM controller 222, such as a mapping table and a flash translation layer (FTL). Alternatively, the separate memory may be a buffer memory that temporarily stores data read from the nonvolatile memory 223 or data to be stored in the nonvolatile memory 223.

Below, for descriptive convenience, “_v” may be attached to elements (e.g., data, a tag, a command/address, etc.) associated with the volatile memory 221. For example, a VM command/address that is output from the module controller 210 to control the volatile memory 221 may be expressed by “CA_v”, and data that is output from the volatile memory 221 under control of the module controller 210 may be expressed by “DT_v”. In more detail, a VM write command for writing data in the volatile memory 221 may be expressed by “WR_v”, and a VM read command for reading data from the volatile memory 221 may be expressed by “RD_v”.

Likewise, “n” may be attached to elements (e.g., data, a tag, a command/address, etc.) associated with the nonvolatile memory 223. For example, an NVM command/address that is output from the module controller 210 to control the nonvolatile memory 223 may be expressed by “CA_n”, and data that is output from the nonvolatile memory 123 under control of the module controller 210 may be expressed by “DT_n”. In more detail, an NVM write command for writing data in the nonvolatile memory 223 may be expressed by “WR_n”, and an NVM read command for reading data from the nonvolatile memory 223 may be expressed by “RD_n”.

As described above, the nonvolatile memory module 200 according to an embodiment of the inventive concept may provide the validity information DQ_INFO associated with data output at a fixed latency RL with reference to a result of performing a cache check operation with respect to read-requested data.

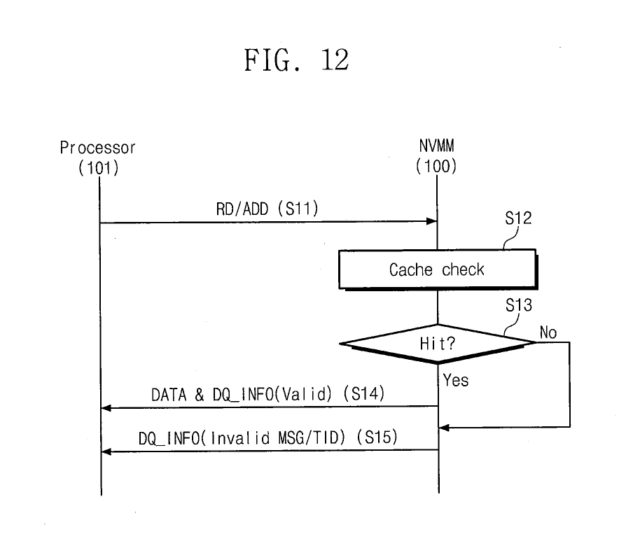

FIG. 12 is a flowchart illustrating a read operation of the nonvolatile memory module 200 of FIG. 11. Referring to FIGS. 1, 11, and 12, the nonvolatile memory module 200 outputs data and validity information DQ_INFO corresponding to the data in response to a read request from the processor 101.

In operation S11, the processor 101 may send a module read command and address (RD and ADD). The nonvolatile memory module 200 may perform a read operation with respect to the volatile memory 221 in response to the received module read command and address (RD and ADD). For example, the module read command and address (RD and ADD) may include a read command for reading data stored in the nonvolatile memory module 200 and a read address corresponding to the read data. The nonvolatile memory module 200 may read data and a tag stored in a portion, which corresponds to the read address, of a region of the volatile memory 221.

In operation 12, the nonvolatile memory module 200 may perform a cache check operation for determining a cache hit or a cache miss based on the read result. As described above, the tag “TAG” includes information about a portion of an address. The nonvolatile memory module 200 may determine whether a cache hit or a cache miss occurs, by comparing the tag “TAG” with the received address.

In operation S13, the process branches according to the cache check result. If a portion of the address is the same as the tag “TAG”, the nonvolatile memory module 200 may determine that the cache hit is generated. Otherwise the nonvolatile memory module 200 may determine that the cache miss is generated.

If the cache hit is generated, in operation S14, the nonvolatile memory module 200 sends the data read from the volatile memory 221 and validity information DQ_INFO to the processor 101. The validity information DQ_INFO includes information about whether the output data corresponds to the cache hit or the cache miss. The processor 101 may determine whether data DT_v received through the validity information DQ_INFO is valid data. That is, the nonvolatile memory module 200 may provide the processor 101 with information about the cache hit as the validity information DQ_INFO so that the processor 101 may recognize the read data as valid data.

If the cache miss is generated, in operation S15, the nonvolatile memory module 200 sends the validity information DQ_INFO, which indicates that data output through the data line DQ is invalid data, to the processor 101. That is, the nonvolatile memory module 200 may output the validity information DQ_INFO indicating the cache miss to the processor 101. In this case, the nonvolatile memory module 200 may provide the processor 101 with the transaction identification TID of data corresponding to the cache miss as additional validity information DQ_INFO. The processor 101 may request data, which is cache-missed later, with reference to the transaction identification TID.

In an embodiment, operation S14 may be performed after a predetermined latency RL elapses from operation S11. That is, the processor 101 may send the module read command and address (RD and ADD) to the nonvolatile memory module 200 and may receive the read data from the nonvolatile memory module 100 after the predetermined latency elapses. In this case, the predetermined latency may be a read latency RL. The read latency RL may be a time or a clock period that is determined according to the operating characteristic of the nonvolatile memory module 200. Information about the read latency RL may be stored in the SPD 240 and may be provided as the device information DI to the processor 101. The processor 101 may control the nonvolatile memory module 200 based on the read latency RL.

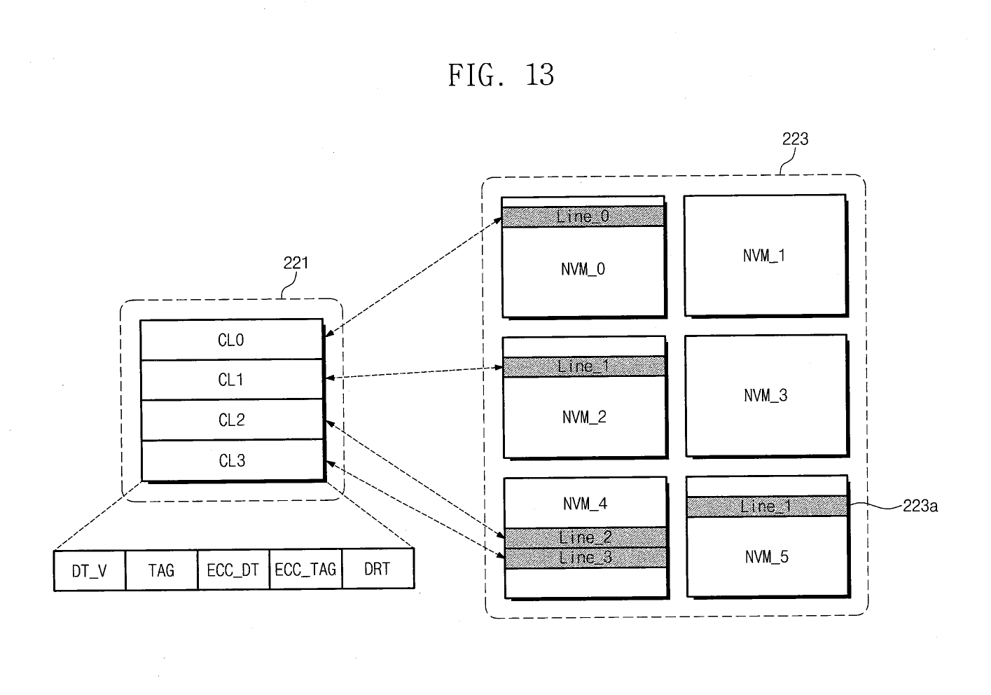

FIG. 13 is a view for describing a cache structure of the volatile memory of FIG. 11. For descriptive convenience, elements which are not needed to describe a cache structure of the volatile memory 221 are omitted. Furthermore, it is assumed that a storage region of the nonvolatile memory 223 is divided into a plurality of regions NVM_O to NVM_5. The plurality of regions NVM_0 to NVM_5 may be regions that are logically divided. The storage region of the nonvolatile memory 223 may further include a storage space as well as the first to fourth regions NVM_0 to NVM_5.

Referring to FIGS. 11 and 13, an access speed of the volatile memory 221 may be faster than that of the nonvolatile memory 223. That is, a portion of data stored in the nonvolatile memory 223 may be stored in the volatile memory 221 so that a speed in which an access operation is performed according to a request of the module controller 210 or the processor 101 may be improved. For example, the volatile memory 221 may be used as a cache memory of the nonvolatile memory 223. For example, the volatile memory 221 may store a portion of data stored in the nonvolatile memory 223 and may output the stored data in response to a request of the module controller 210 or the processor 101.

In an embodiment, the volatile memory 221 may have a direct mapping relation with the nonvolatile memory 223. For example, the volatile memory 221 may include a plurality of cache lines CL0 to CL3. A cache line CL may indicate a storage space that stores cached data and tag “TAG”, a data error correction code ECC_DT, a tag error correction code ECC_TAG, and dirty information DRT.

The cache line may indicate a minimum access unit of a request of the module controller 210 or the processor 101. The volatile memory 221 may have a storage capacity that corresponds to the plurality of entries CL0 to CL3. The tag “TAG” may be at least a portion of an address corresponding to data DT_v stored in the same entry. The data error correction code ECC_DT may be an error correction code of the data DTv stored in the same entry. The tag error correction code ECC_TAG may be an error correction code of the tag “TAG” stored in the same entry. The dirty information DRT may indicate dirty information about the data DT_v stored in the same entry.

The nonvolatile memory 223 may include the plurality of regions NVM_0 to NVM_5. Each of the plurality of regions NVM_0 to NVM_5 may include a plurality of lines Line0 to Line3. In an embodiment, each of the lines Line0 to Line3 may indicate a storage space that corresponds to a data access unit of a request of the processor 101 or the module controller 210.

For example, the memory region NVM_0 may include the lines Line0 to Line3 corresponding to a cache unit. The lines Line0 to Line3 may correspond to the cache lines CL0 to CL3, respectively. That is, the line Line0 may correspond to the cache line CL0, and the line Line1 may correspond to the cache line CL1. The memory region NVM_1 may include the cache lines Line0 to Line3, which correspond to the plurality of cache lines CL0 to CL3, respectively. Likewise, each of the memory regions NVM_2 to NVM_5 may include the lines Line0 to Line3, which correspond to the plurality of cache lines CL0 to CL3, respectively.

As described above, the volatile memory 221 may have a direct mapping relation with the nonvolatile memory 223. The cache line CL0 of the volatile memory 221 may correspond to each of the lines Line0 of the plurality of regions NVM_0 to NVM_5 and may store data DT_v stored in one of the lines Line0 of the plurality of regions NVM_0 to NVM_5. In other words, the data DT_v stored in the cache line CL0 may correspond to one of the lines Line0 of the plurality of regions NVM_0 to NVM_5.

The cache line Line0 may include a tag “TAG” associated with the stored data DT_v. In an embodiment, the tag “TAG” may be information indicating whether the data DT_v stored in the cache line CL0 corresponds to any one of the lines Line0 of the plurality of regions NVM_0 to NVM_5.

In an embodiment, each of the plurality of lines Line0 to Line3 may be selected or recognized by the address ADD provided from the processor 101. That is, at least one of the plurality of lines Line0 to Line3 of each of the plurality of memory regions NVM_0 to NVM_5 may be selected by the address ADD provided from the processor 101, and an access operation may be performed with respect to the selected line.

Each of the plurality of cache lines CL0 to CL3 may be selected or distinguished by at least a portion of the address ADD provided from the processor 101. That is, at least one of the plurality of cache lines CL0 to CL3 may be selected by at least a portion of the address ADD provided from the processor 101, and an access operation may be performed with respect to the selected cache line.

The tag “TAG” may include at least a portion of the address ADD provided from the processor 101 or the rest thereof. For example, the case that at least one of the plurality of cache lines CL0 to CL3 is selected by a portion of the address ADD and a tag “TAG”_v from the selected cache line is included in the address ADD may be determined as a cache hit is generated. Alternatively, the case that at least one of the plurality of cache lines CL0 to CL3 is selected by a portion of the address ADD and a tag “TAG”_v from the selected cache line is not included in the address ADD may be determined as a cache miss is generated.

As described above, the nonvolatile memory module 200 may use the volatile memory 221 as a cache memory, thereby improving the performance of the nonvolatile memory module 200. In this case, the nonvolatile memory module 200 may determine the occurrence of a cache hit or a cache miss, based on a tag “TAG” stored in the volatile memory 221.

In an embodiment, a data transaction method between the volatile memory 221 and the nonvolatile memory 223 will be described below with reference to accompanying drawings. However, embodiments to be described below are only examples for describing the scope and spirit of the inventive concept easily, and thus the embodiments are not limited thereto. In addition, embodiments of the inventive concept are described as the volatile memory 221 is used as a cache memory of the nonvolatile memory 223, but the embodiments are not limited thereto.

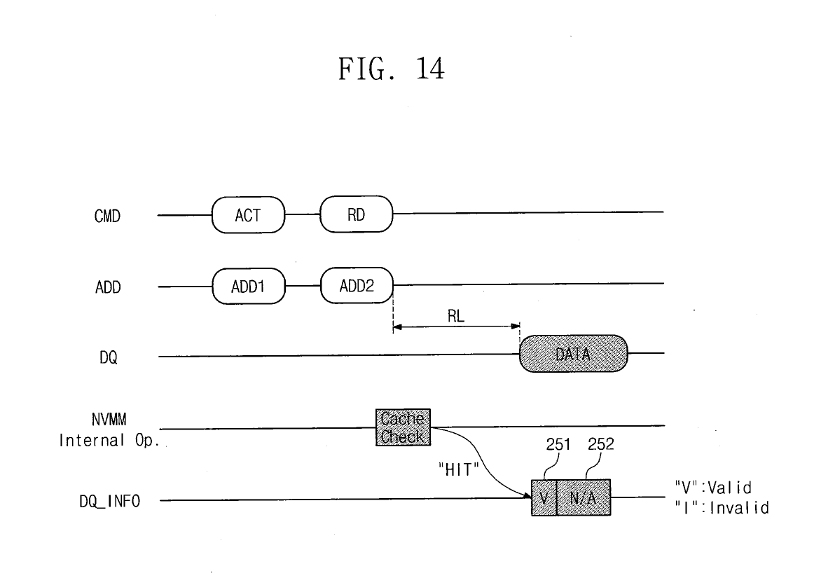

FIG. 14 is a timing diagram for describing a read operation of FIG. 12 in detail. Referring to FIG. 14, the nonvolatile memory module 200 may receive a module read command from the processor 101. For example, the nonvolatile memory module 200 may receive a first address ADD1 at the same time with the active command ACT and may receive a read command RD and a second address ADD2.

An internal cache check operation of the nonvolatile memory module 200 by the module controller 210 may be performed in response to the received signals. For example, the module controller 210 may output the NVM command/address CA_n and the VM command/address CA_v. The volatile memory 221 may output data DT_v and a tag “TAG”_V that are stored in a portion, which corresponds to the address ADD1 or ADD2, of a region of the volatile memory 221 in response to the VM read command/address CA_v. For example, as described above, the volatile memory 221 may output the data DT v through the memory data line MDQ by driving a voltage of the memory data line MDQ on the basis of the data DT_v . The volatile memory 221 may output the tag “TAG”_v through the tag data line TDQ by driving a voltage of the tag data line TDQ on the basis of the tag “TAG”_v. The module controller 210 may receive the tag “TAG”_v through the tag data line TDQ and may determine whether a cache hit or a cache miss is generated, based on a result of comparing the received tag “TAG”_v with the address ADD1 or ADD2.

Data may be output to the volatile memory 221 through the data line DQ after the read command RD and the second address ADD2 are received and a fixed latency RL elapses. In this case, the output data is data that is determined as being cache-hit when a cache check operation is performed by the module controller 210. Accordingly, the module controller 210 may output the validity information DQ_INFO to be provided to the processor 101 through a separate pin. That is, the validity information DQ_INFO may include a validity portion 251 indicating that data read from the volatile memory 221 is valid data. The validity information DQ_INFO may include a transaction identification portion 252 to be described later. However, when there is determined that data is valid, since the transaction identification portion 252 is unnecessary, it may be ignored by the processor 101. The processor 101 may determine whether data is valid, based on the validity information DQ_INFO.

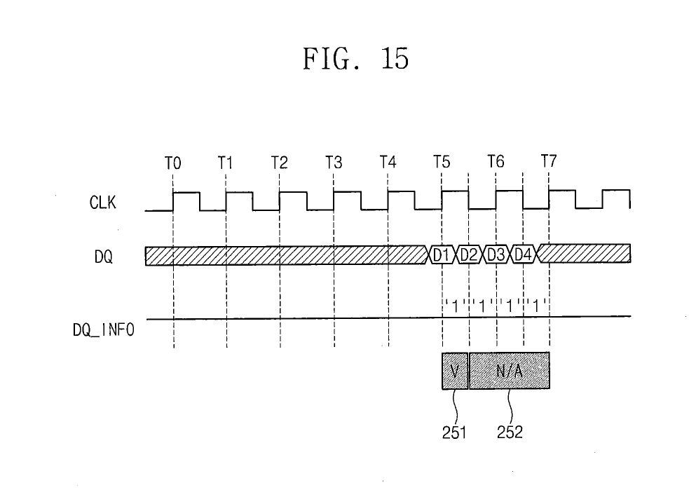

FIG. 15 is a timing diagram illustrating an implementation of data and validity information DQ_INFO of FIG. 14. Referring to FIG. 15, it is assumed that data read requested by the processor 101 is sequentially output through the data line DQ. For ease of description, a read command, an address, etc. are omitted in FIG. 15. Pieces of data D1, D2, D3, and D4 are output through a plurality of pins after a specific latency in response to a read command and an address. In synchronization with the output of the data, the validity information DQ_INFO according to an embodiment of the inventive concept may be output through a separately allocated pin.

The pieces of data D1, D2, D3, and D4 may be output in synchronization with rising and falling edges of a clock signal CLK. In addition, the validity information DQ_INFO may be output to the processor 101 through the allocated pin in synchronization with the clock signal CLK. The validity information DQ_INFO includes the validity portion 251 and the transaction identification portion 252. If the data D1 to D4 output from the volatile memory 221 correspond to the cache hit, the validity portion 251 of the validity information DQ_INFO having a value “V” indicating that the data D1 to D4 is valid may be output. For example, the validity portion 251 having a logical value of “1” may be output. In addition, there may be no problem even though the transaction identification portion 252 corresponding to valid data is ignored by the processor 101. Accordingly, the transaction identification portion 252, for example, having a logical value of “111” may be output. In the embodiment illustrated in FIG. 15, the number of bits of the validity portion 251 and the number of bits of the transaction identification portion 252 are “1” and “3”. However, the number of bits of each of the validity portion 251 and the transaction identification portion 252 may be changed according to embodiments.

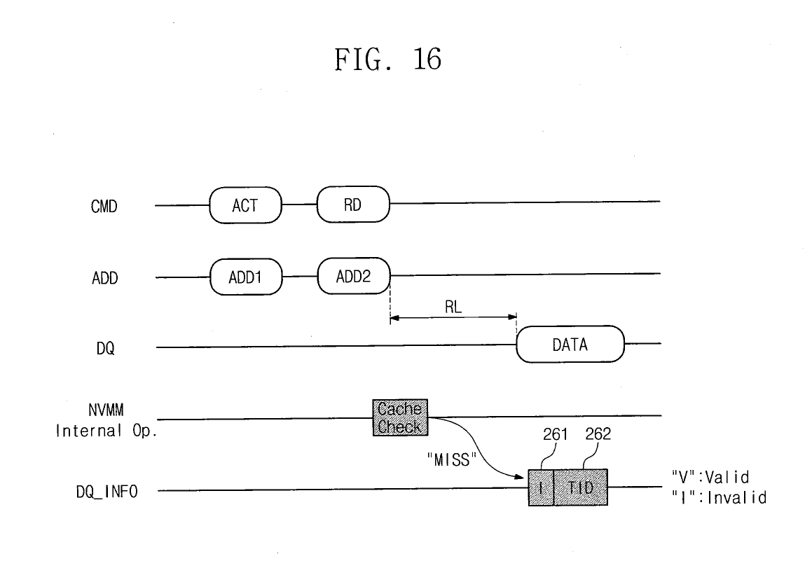

FIG. 16 is a timing diagram for describing the read operation of FIG. 12 in detail. The validity information DQ_INFO that is output from the nonvolatile memory module 200 according to an embodiment of the inventive concept when the cache miss is generated is illustrated in FIG. 16. The nonvolatile memory module 200 may receive a module read command from the processor 101. For example, the nonvolatile memory module 200 may receive a first address ADD1 at the same time with the active command ACT and may receive a read command RD and a second address ADD2.

An internal cache check operation of the nonvolatile memory module 200 by the module controller 210 may be performed in response to the received command and address. The cache check operation of the nonvolatile memory module 200 is described with reference to FIG, 14, and a description thereof is thus omitted. The module controller 210 may receive the tag “TAG” v corresponding to a read-requested address through the tag data line TDQ and may determine whether a cache hit or a cache miss is generated, based on a result of comparing the received tag “TAG”_v with the address ADD1 or ADD2.

Data may be output to the volatile memory 221 through the data line DQ after the read command RD and the second address ADD2 are received and a fixed latency RL elapses. In this case, it is assumed that a result of performing the cache check operation with respect to the output data corresponds to the cache miss. In this case, the module controller 210 may output the validity information DQ_INFO through a separate pin for handshaking with the processor 101. The validity information DQ_INFO may include a validity portion 261 indicating that data read from the volatile memory 221 is valid data. The validity information DQ_INFO may include a transaction identification portion 262. The transaction identification portion 262 may be implemented through numbering of a monotonic increase form of a transaction corresponding to the cache miss.

The processor 101 may recognize that data is cache-missed data, based on the validity information DQ_INFO. The processor 101 may again request a data read operation at a suitable time based on the transaction identification TID.

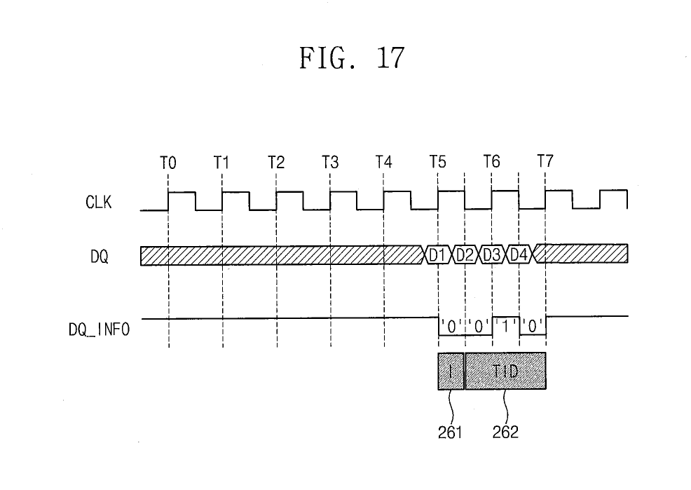

FIG. 17 is a timing diagram illustrating an implementation of data and validity information DQ_INFO of FIG. 16. Referring to FIG. 17, it is assumed that data read requested by the processor 101 is sequentially output through the data line DQ. For ease of description, a read command, an address, etc. are omitted in FIG. 17. Pieces of data D1, D2, D3, and D4 are output through a plurality of pins after a specific latency RL in response to a read command and an address. In synchronization with the output of the data, the validity information DQ_INFO according to an embodiment of the inventive concept may be output through a separately allocated pin.

The pieces of data D1, D2, D3, and D4 may be output in synchronization with rising and falling edges of a clock signal CLK. In addition, the validity information DQ_INFO may be output to the processor 101 through the allocated pin in synchronization with the clock signal CLK. The validity information DQ_INFO includes the validity portion 261 and the transaction identification portion 262. If the data D1 to D4 output from the volatile memory 221 correspond to the cache miss, the validity portion 261 of the validity information DQ_INFO having a value “I” indicating that the data D1 to D4 is invalid may be output. For example, the validity portion 261 having a logical value of “0” may be output. Furthermore, a transaction identification TID corresponding to the data D1 to D4 determined as invalid data due to the cache miss may be output. If the transaction identification TID has a logic value of “010”, the logic value of “010” corresponding to the transaction identification TID may be sent to the processor 101 through a pin provided for the validity information DQ_INFO.

It should be well understood that the number of bits of the validity information DQ_INFO or the number of bits of each of the validity portion 261 and the transaction identification portion 262 constituting the validity information DQ_INFO is not limited to the above description.

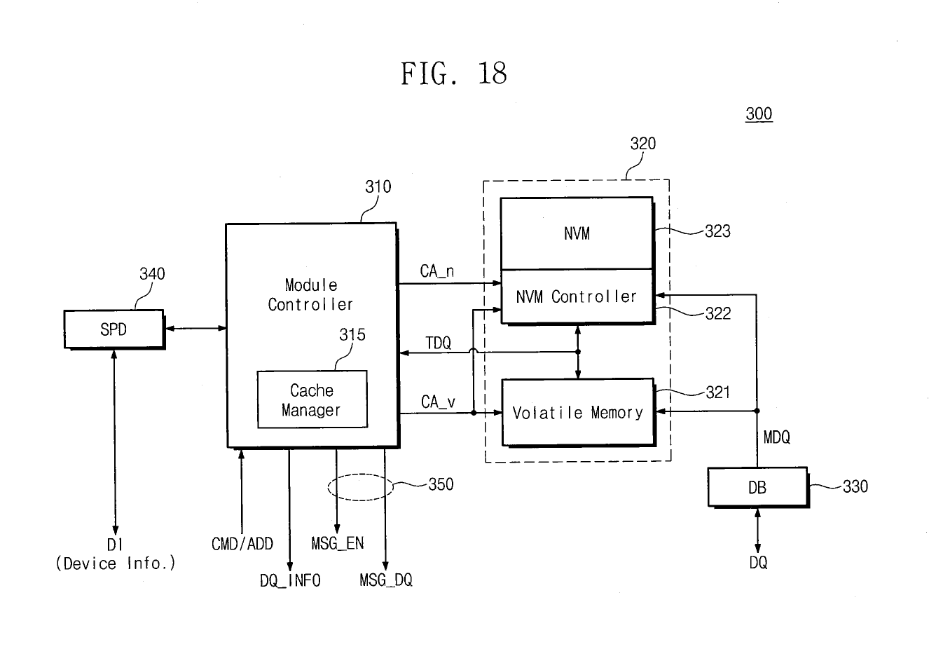

FIG. 18 is a block diagram illustrating other features of the memory module according to another embodiment of the inventive concept. Referring to FIGS. 1 and 18, a nonvolatile memory module 300 may include a module controller 310, a heterogeneous memory device 320, a data buffer 330, and a SPD 340. Operations and configurations of the heterogeneous memory device 320, the data buffer 330, and the SPD 340 are substantially the same as those of the heterogeneous memory device 220, the data buffer 230, and the SPD 240 of FIG. 11, and a description thereof is thus omitted below.

The module controller 310 may receive a module command/address CA from the processor 101 and may control the heterogeneous memory device 320 in response to the received module command/address CA. For example, the module controller 310 may provide the heterogeneous memory device 320 with the NVM command/address CA_n and the VM command/address CA_v in response to the module command/address CA from the processor 101.

The module controller 310 may determine whether the cache hit or the cache miss is generated, based on the module command/address CA from the processor 101 and the tag “TAG”. The module controller 310 may determine whether the cache hit or the cache miss is generated, by comparing the module command/address CA from the processor 101 and the tag “TAG”. To determine the cache hit or the cache miss, the module controller 310 may include a cache manager 315.

The cache manager 315 may assign and manage transaction identifications TID with respect to cache-missed addresses. For example, the cache manager 315 may perform a cache check operation and may assign the transaction identification TID to a read request or address corresponding to the cache miss as a consequence of determining In this case, transaction identifications of a monotonic increase form may be assigned to a plurality of read requests or addresses corresponding to the cache miss. The transaction identifications TID may be provided to the processor 101 together with the validity information DQ_INFO indicating whether the cache hit is generated.

Here, the tag “TAG” may include a portion of an address that corresponds to data stored in the volatile memory 221. In an embodiment, the module controller 310 may exchange the tag “TAG” with the volatile memory 321 through the tag data line TDQ. In an embodiment, when data is written in the volatile memory 321, the tag “TAG” corresponding to the data may be written in the volatile memory 221 together with the data under control of the module controller 310.

Read-requested data may be output through the data line DQ after a fixed latency RL in response to a read command from the processor 101. The module controller 310 may send the validity information DQ_INFO of data output through the data line DQ to the processor 101 based on a result of the cache check operation. The validity information DQ_INFO may include validity and a transaction identification TID associated with data output through the data line DQ. The processor 101 may be provided with cache-missed data, which is capable of being output at a point in time after the latency RL, with reference to the validity information DQ_INFO. That is, the processor 101 may again request the cache-missed data with reference to the transaction identification TID.

In addition, the module controller 310 may send the validity information DQ_INFO of data output through the data line DQ to the processor 101 based on the cache check result. The validity information DQ_INFO may include validity and a transaction identification TID associated with data output through the data line DQ. The processor 101 may be provided with cache-missed data, which is capable of being output at a point in time after the latency RL, with reference to the validity information DQ_INFO. That is, the processor 101 may again request the cache-missed data with reference to the transaction identification TID.

The module controller 310 may send message information MSG_EN and MSG_DQ (refer to 350) together with the validity information DQ_INFO to the processor 101. The validity information DQ_INFO is information output in synchronization with a command/address and data, while the message information MSG_EN and MSG_DQ is output without synchronization with the command/address and data. The message information 350 may be provided with respect to a read request determined as the cache miss by using unidirectional pins providing notification that the nonvolatile memory module 300 is ready to output. In an embodiment, the message information 350 may be output through two pins. However, it should be understood that the message information 350 is output serially through one pin. The message information 350 may include a transaction identification, which corresponds to data capable of being output, from among transaction identifications determined previously cache-missed. The processor 101 may again send a read request, which corresponds to a response indicating invalid data, to the nonvolatile memory module 300 with reference to the message information 350 (i.e., MSG_EN and MSG_DQ). In addition, it should be understood that the message information 350 (i.e., MSG_EN and MSG_DQ) further includes a variety of information as well as the transaction identification TID. For example, the message information 350 (i.e., MSG_EN and MSG_DQ) may include tag information TAG associated with prepared data.

According to the embodiment described with reference to FIG. 18, the nonvolatile memory module 300 may output the validity information DQ_INFO, which corresponds to the result of the cache check operation performed with respect to the read request, in synchronization with data. Furthermore, the nonvolatile memory module 300 may provide the processor 101 with the message information MSG_EN and MSG_DQ output without synchronization with data in a cache miss situation. The message information MSG_EN and MSG_DQ may include a transaction identification and the like of data that is capable of being output internally.

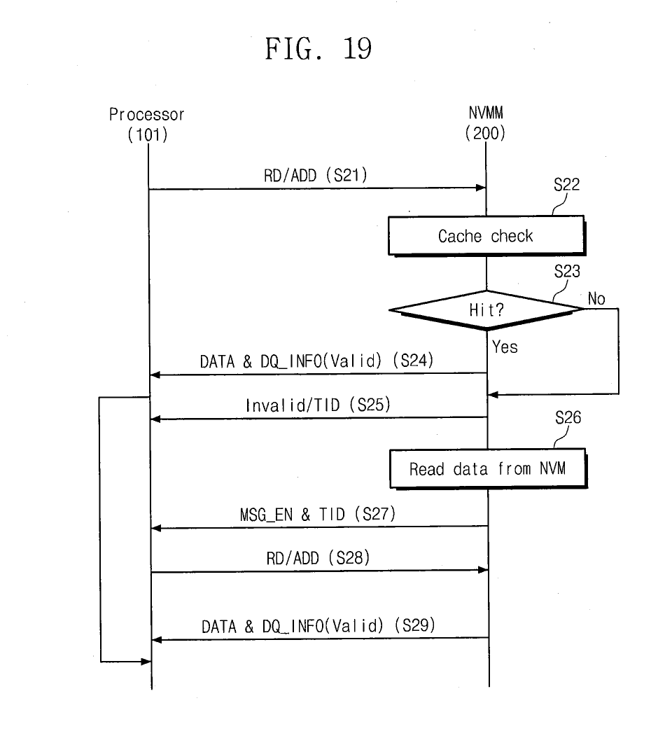

FIG. 19 is a flowchart illustrating a handshaking procedure between the processor 101 and the nonvolatile memory module 300 of FIG. 18. Referring to FIGS. 18 and 19, the nonvolatile memory module 300 outputs data and validity information DQ_INFO corresponding to the data in response to a read request from the processor 101.

In operation S21, the processor 101 sends a module read command and address (RD and ADD). The nonvolatile memory module 300 performs a read operation with respect to the volatile memory 321 in response to the received module read command and address (RD and ADD). For example, the module read command and address (RD and ADD) may include a read command for reading data stored in the nonvolatile memory module 300 and a read address corresponding to the read data. The nonvolatile memory module 300 may read data and a tag stored in a portion, which corresponds to the read address, of a region of the volatile memory 321.

In operation S22, the nonvolatile memory module 300 may perform a cache check operation for determining a cache hit or a cache miss based on the read result. As described above, the cache manager 315 may perform the cache check operation by comparing the address received from the processor 101 with the tag “TAG”.

In operation S23, the process branches according to the cache check result. If a portion of the address is the same as the tag “TAG”, the nonvolatile memory module 300 may determine that the cache hit is generated. Otherwise the nonvolatile memory module 300 may determine that the cache miss is generated.

If the cache hit is generated, in operation S24, the nonvolatile memory module 300 sends the data read from the volatile memory 321 and validity information DQ_INFO to the processor 101. The validity information DQ_INFO includes information about whether the output data corresponds to the cache hit or the cache miss. The processor 101 may determine whether data DT_v received through the validity information DQ_INFO is valid data. That is, the nonvolatile memory module 300 may provide the processor 101 with information about the cache hit as the validity information DQ_INFO so that the processor 101 may recognize the read data as valid data. If data provided from the nonvolatile memory module 300 is checked as valid data, the overall data read operation of the processor 101 may end.

If the cache miss is generated, in operation S25, the nonvolatile memory module 300 sends the validity information DQ INFO, which indicates that data output through the data line DQ is invalid data, to the processor 101. That is, the nonvolatile memory module 300 may output the validity information DQ_INFO indicating the cache miss to the processor 101. In this case, the nonvolatile memory module 300 may provide the processor 101 with the transaction identification TID of data corresponding to the cache miss as additional validity information DQ_INFO. The processor 101 may store the transaction identification TID in a table form.

After the validity information DQ_INFO indicating the cache miss is provided to the processor 101, in operation S26, the nonvolatile memory module 300 may read data, which is not cached in the volatile memory 321, from the nonvolatile memory 323. The nonvolatile memory module 300 may store the read data in a cache line of the volatile memory 321 or in a separate volatile memory region.

In operation S27, if it is ready to output data determined as the cache miss, the nonvolatile memory module 300 may send the message information MSG_EN and MSG_DQ to the processor 101. For example, the nonvolatile memory module 300 may activate a message enable signal MSG_EN and may provide the processor 101 with the transaction identification TID, which corresponds to data ready to output, through a message pin MSG_DQ. The message information MSG_EN and MSG_DQ may be provided without synchronization with data.

In operation S28, the processor 101 may receive the message information MSG_EN and MSG_DQ and may issue a read command corresponding thereto. An address corresponding to the transaction identification TID may be separately managed by the processor 101.

In step S29, the nonvolatile memory module 300 may output data requested by the processor 101. In this case, the validity information DQ_INFO providing notification that the requested data is cached in the volatile memory 321 may be output together with data.

There is described a handshaking method between the processor 101 and the nonvolatile memory module 300 by using the validity information DQ_INFO output in synchronization with data and the message information MSG_EN and MSG_DQ output without synchronization with data.

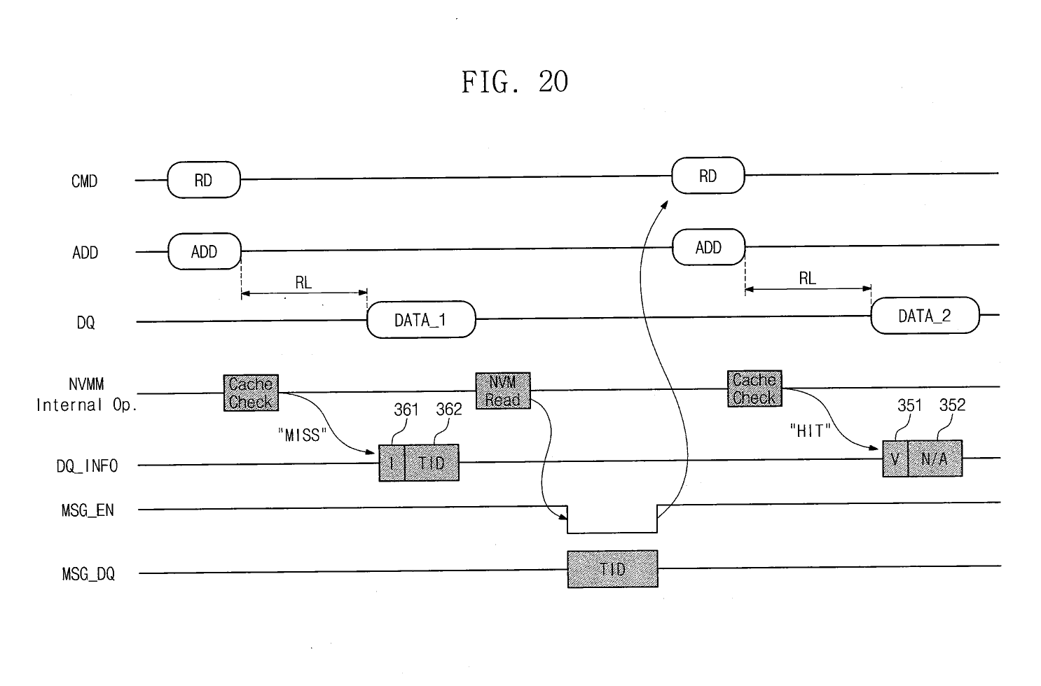

FIG. 20 is a timing diagram for describing the handshaking operation of FIG. 19 in detail. Referring to FIG. 20, in a cache miss situation, the nonvolatile memory module 300 according to an embodiment of the inventive concept may send the validity information DQ_INFO and the message information MSG_EN and MSG_DQ to the processor 101. In this case, the processor 101 may again read data corresponding to the cache miss with reference to the validity information DQ_INFO and the message information MSG_EN and MSG_DQ.

The processor 101 provide the nonvolatile memory module 300 with a read command RD and an address ADD for a data read request. The nonvolatile memory module 300 may perform a read operation with respect to the volatile memory 321 in response to the received read command RD and address ADD. In detail, the cache manager 315 in the module controller 310 may perform an internal cache check operation in response to the received command and address. The cache check operation of the nonvolatile memory module 300 is described with reference to FIG. 14, and a description thereof is thus omitted. The module controller 310 may receive the tag “TAG”_v corresponding to a read-requested address through the tag data line TDQ and may determine whether a cache hit or a cache miss is generated, based on a result of comparing the received tag “TAG”_v with the address ADD.

First data DATA_1 may be output to the volatile memory 321 through the data line DQ after the read command RD and the address ADD are received and a specific latency RL elapses. In this case, it is assumed that a result of performing, by the module controller 310, the cache check operation with respect to the first data DATA_1 corresponds to the cache miss. In this case, the module controller 310 may output the validity information DQ_INFO for handshaking with the processor 101. The validity information DQ_INFO may include a validity portion (i.e., “I”) 361 indicating that the first data DATA_1 is invalid data. The validity information DQ_INFO may further include a transaction identification portion (i.e., TID) 362. The transaction identification portion 362 may be implemented through numbering of a monotonic increase form of a transaction corresponding to the cache miss.

The processor 101 may recognize that the first data DATA_1 is cache-missed invalid data, based on the validity information DQ_INFO. The processor 101 may store and manage overall information about the cache-missed read request with reference to the transaction identification TID.

After sending the validity information DQ_INFO, the nonvolatile memory module 300 may internally access the nonvolatile memory 323 to read the cache-missed data. If it is ready to output the cache-missed data, the nonvolatile memory module 300 may send the message information MSG_EN and MSG_DQ to the processor 101. The message information MSG_EN and MSG_DQ may be provided through one signal line or by using a separate pin for outputting the message enable signal MSG_EN and the message data signal MSG_DQ. If the message enable signal MSG_EN and the message data signal MSG_DQ are provided by using the separate pin, the message data signal MSG_DQ may include a transaction identification TID corresponding to data ready to output. Unlike the validity information DQ_INFO output in synchronization with data, the message information MSG_EN and MSG_DQ may be output without synchronization with data. That is, the message information MSG_EN and MSG_DQ may be output when the nonvolatile memory module 300 fetches the cache-missed data and the fetched data is ready to output.

The processor 101 may again send the read command RD and the address ADD to the nonvolatile memory module 300 in response to an output of the message information MSG_EN and MSG_DQ. In this case, the read command RD and the address ADD may be generated on the basis of the transaction identification TID included in the message information MSG_EN and MSG_DQ.

The nonvolatile memory module 300 may perform the cache check operation with respect to the volatile memory 321 in response to the received read command RD and address ADD. If the cache hit is generated, the nonvolatile memory module 300 may output the validity information DQ_INFO in synchronization with second data DATA_2 output after the read latency RL. In this case, the output validity information DQ_INFO may include a validity portion 351 meaning that the second data DATA_2 is valid. In the cache hit, since a transaction identification portion 352 is meaningless, it may be provided in a dummy state.

There is described a method of outputting the validity information DQ_INFO in synchronization with data and the message information MSG_EN and MSG_DQ without synchronization with data when a read operation is requested with respect to the nonvolatile memory module 300. The processor 101 may recognize that the synchronized and output data is invalid data, on the basis of the validity information DQ_INFO and may receive a transaction identification. The processor 101 may check a transaction identification TID of data ready to output through the message information MSG_EN and MSG_DQ and may again perform a read operation associated with data that is not obtained due to the cache miss.

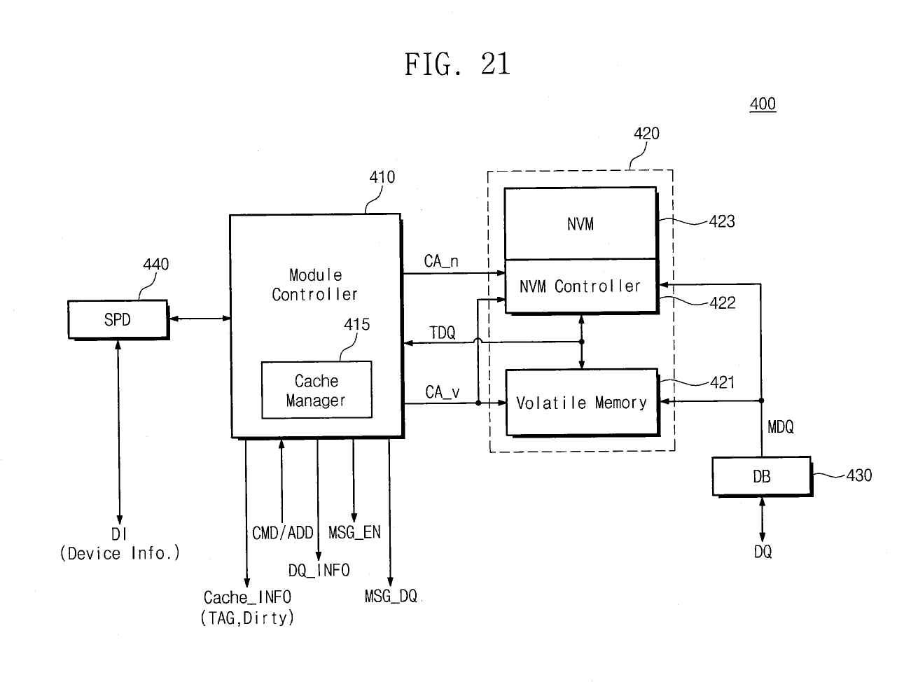

FIG. 21 is a block diagram illustrating the memory module of FIG. 1 according to another embodiment of the inventive concept. Referring to FIGS. 1 and 21, a nonvolatile memory module 400 may include a module controller 410, a heterogeneous memory device 420, a data buffer 430, and a SPD 440. Here, operations and configurations of the heterogeneous memory device 420, the data buffer 430, and the SPD 440 are substantially the same as those of the heterogeneous memory device 220, the data buffer 230, and the SPD 440 of FIG. 11, and a description thereof is thus omitted below.

The module controller 410 may receive a module command/address CMD/ADD from the processor 101 and may control the heterogeneous memory device 420 in response to the received module command/address CMD/ADD. For example, the module controller 410 may provide the heterogeneous memory device 420 with the NVM command/address CA_n and the VM command/address CA v in response to the module command/address CMD/ADD from the processor 101.

The module controller 410 may determine whether the cache hit or the cache miss is generated, based on the module command/address CMD/ADD from the processor 101 and a tag “TAG”. The module controller 410 may determine whether the cache hit or the cache miss is generated, based on the module command/address CMD/ADD from the processor 101 and the tag “TAG”. To determine the cache hit or the cache miss, the module controller 410 may include a cache manager 415.

The cache manager 415 may assign and manage transaction identifications TID with respect to cache-missed addresses. For example, the cache manager 415 may perform a cache check operation and may assign the transaction identification TID to a read request or address corresponding to the cache miss as a consequence of determining. In this case, transaction identifications of a monotonic increase form may be assigned to a plurality of read requests or addresses corresponding to the cache miss. The transaction identifications TID may be provided to the processor 101 together with the validity information DQ_INFO indicating whether the cache hit is generated.

Here, the tag “TAG” may include a portion of an address ADD that corresponds to data stored in the volatile memory 421. In an embodiment, the module controller 410 may exchange the tag “TAG” with the volatile memory 421 through the tag data line TDQ. In an embodiment, when data is written in the volatile memory 421, the tag “TAG” corresponding to the data may be written in the volatile memory 221 together with the data under control of the module controller 410.

Read-requested data may be output through the data line DQ after a specific latency RL in response to a read command from the processor 101. The module controller 410 may send the validity information DQ_INFO of data output through the data line DQ to the processor 101 based on the cache check result. The validity information DQ_INFO may include validity and a transaction identification TID associated with data output through the data line DQ. In addition, when the cache miss is generated, the module controller 410 may output the message information MSG_EN, MSG_DQ without synchronization with data together with the validity information DQ_INFO that is output in synchronization with data. In addition, the module controller 410 may provide the processor 101 with cache information Cache_INFO in synchronization with the validity information DQ_INFO. The cache information Cache_INFO may include a tag “TAG” of the read-requested data or dirty information of a read-requested cache line. It should be understood that the module controller 410 has a separate pin to output the cache information Cache_INFO.

Features of the nonvolatile memory modules 100, 200, and 300 according to embodiments of the inventive concept are described. Here, the handshaking method according to an embodiment of the inventive concept is described by using an example where the volatile memories 121, 221, and 321 are used as a cache memory. However, embodiments of the inventive concept are not limited thereto. In a memory module including memories of which access speeds are different from each other, features of the inventive concept may be applicable to all memory modules that comply with the same read latency standard.

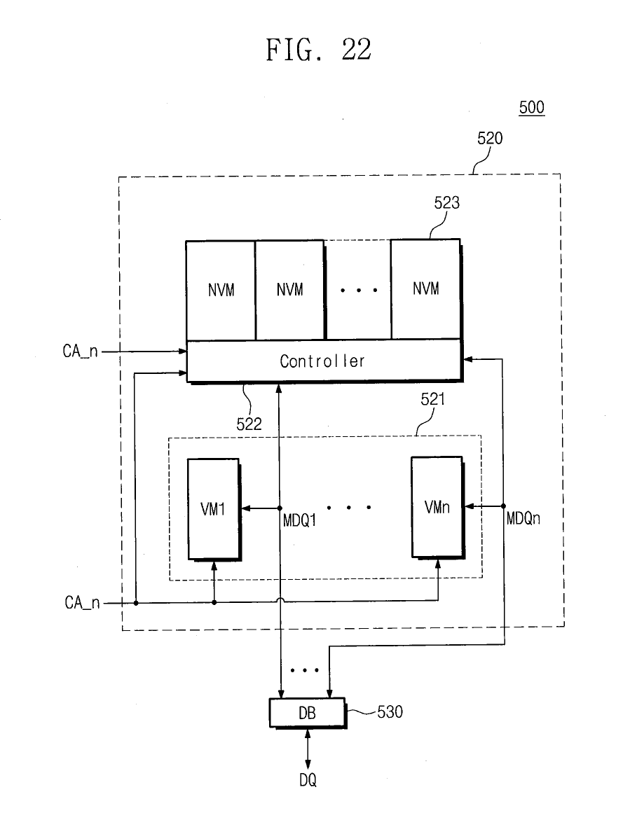

FIG. 22 is a block diagram illustrating the nonvolatile memory module of FIG. 1, according to another embodiment of the inventive concept. For ease of illustration, elements (e.g., a module controller and an SPD) except for a heterogeneous memory device 520 and a data buffer 530 are omitted. Also, for descriptive convenience, a detailed description associated with the above-described elements is omitted. Referring to FIG. 22, the nonvolatile memory module 500 includes the heterogeneous memory device 520 and the data buffer 530.

Unlike the heterogeneous memory device 100 of FIG. 2, the heterogeneous memory device 520 of FIG. 22 includes a plurality of volatile memories 521, an NVM controller 522, and a plurality of nonvolatile memories 523. Each of the volatile memories 521, the NVM controller 522, and the nonvolatile memories 523 may be implemented with a separate die, a separate chip, or a separate package. Each of the volatile memories 521, the NVM controller 522, and the nonvolatile memories 523 of the nonvolatile memory device 520 may be implemented with a separate chip, and the separate chips may be implemented in one package through a multi-chip package (MCP).

Each of the plurality of volatile memories 521 is configured to share the memory data line MDQ with the NVM controller 522. For example, a first volatile memory VM1 may share the first memory data line MDQ1 with the NVM controller 522. The first memory data line MDQ1 may be connected with the data buffer 530. In an embodiment, the first memory data line MDQ1 may include eight lines. An n-th volatile memory VMn may share an n-th memory data line MDQn with the NVM controller 522. The n-th memory data line MDQn may be connected with the data buffer 530. In an embodiment, the n-th memory data line MDQn may include eight lines. Each of the plurality of volatile memories 521 may share a corresponding one of the memory data lines MDQ1 to MDQn with the NVM controller 522, and the plurality of memory data lines MDQ1 to MDQn may be connected with one data buffer 530.

The data buffer 530 may be connected with the processor 101 (refer to FIG. 1) through the data line DQ. In this case, the data line DQ may include lines of which the number is determined according to the number of the memory data lines MDQ1 to MDQn.

In an embodiment, the nonvolatile memory module 500 of FIG. 22 may operate according to an operation method described with reference to FIGS. 3 to 21. For example, at first timing when the active command ACT_n is received, the nonvolatile memory module 500 may receive an address, which is associated with the volatile memories 521 and the nonvolatile memories 523, through address lines. At second timing when a command CMD0 to CMD2 is received, the nonvolatile memory module 500 may receive an address, which is associated with the volatile memories 521 and the nonvolatile memories 523, through some of the address lines and may receive a nonvolatile extended address, which is associated with the volatile memories 521 and the nonvolatile memories 523, through option or reserved lines of the address lines.

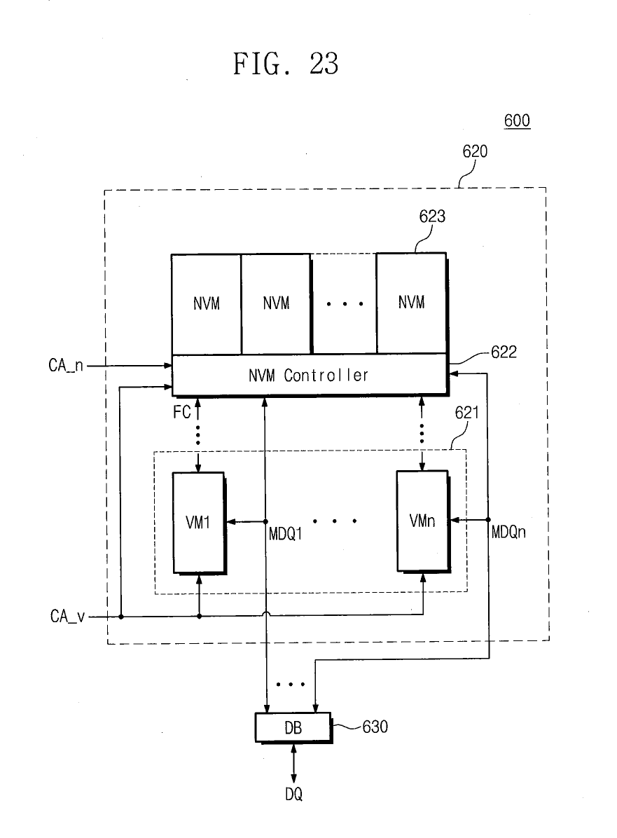

FIG. 23 is a block diagram illustrating the nonvolatile memory module of FIG. 1, according to another embodiment of the inventive concept. For descriptive convenience, a description associated with elements described with reference to FIG. 22 is omitted. Referring to FIG. 23, the nonvolatile memory module 600 includes a heterogeneous memory device 620 and a data buffer 630. The heterogeneous memory device 620 includes a plurality of volatile memories 621, an NVM controller 622, and a plurality of nonvolatile memories 623.

Unlike the heterogeneous memory device 520 of FIG. 22, the heterogeneous memory device 620 includes a dedicated flush channel FC. The dedicated flush channel FC provides a data transmission path between each of the volatile memories 621 and the NVM controller 622. The nonvolatile memory module 600 may perform a flush operation of writing data stored in the volatile memories 621 to the nonvolatile memories 623. The nonvolatile memory module 600 may control the heterogeneous memory device 620 such that data is provided from the volatile memories 621 to the NVM controller 622 through the dedicated flush channel FC.

In an embodiment, the nonvolatile memory module 600 of FIG. 23 may operate according to an operation method described with reference to FIGS. 3 to 21.

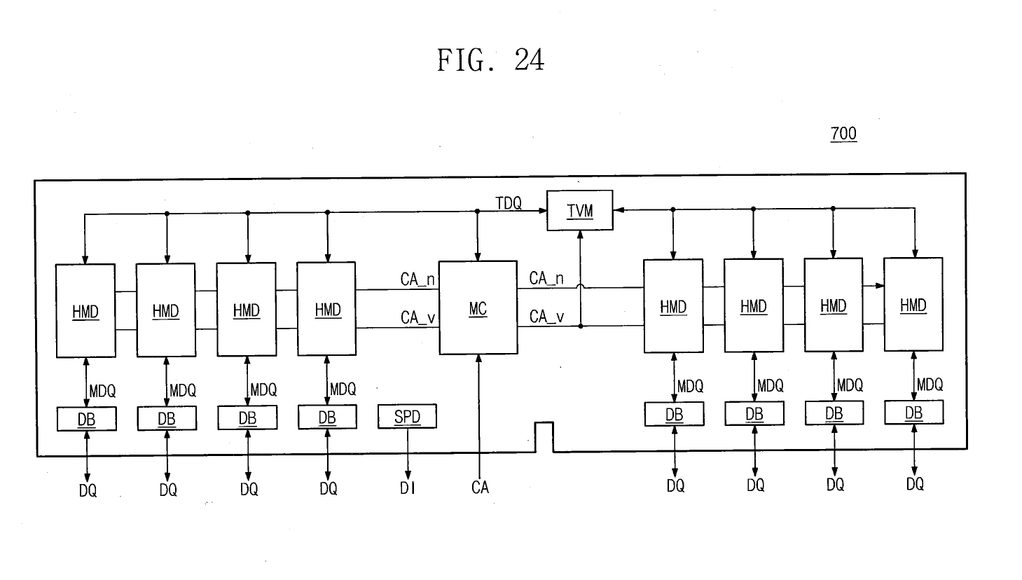

FIG. 24 is a block diagram illustrating the nonvolatile memory module of FIG. 1, according to another embodiment of the inventive concept. Referring to FIG. 24, a nonvolatile memory module 700 includes a module controller MC, a plurality of heterogeneous memory devices HMD, a plurality of data buffers DB, an SPD, and a tag dedicated volatile memory TVM. In an embodiment, the nonvolatile memory module 700 may have the form of a load reduced dual in-line memory module (LRDIMM). For descriptive convenience, a duplicated description of above-described elements is omitted.

As described above, the module controller MC receives a module command/address CA from the processor 101 (refer to FIG. 1) and outputs the NVM command/address CA_n and the VM command/address CA_v in response to the received module command/address CA. The NVM command/address CA_n and the VM command/address CA_v may be provided to the heterogeneous memory devices HMD through different buses.

Each of the plurality of heterogeneous memory devices HMD may be implemented with a separate package and may be one of the heterogeneous memory devices 100 to 600 described with reference to FIGS. 1 to 22. As described above, each of the plurality of heterogeneous memory devices HMD may operate in response to the NVM command/address CA_n and the VM command/address CA_v from the module controller MC. In an embodiment, the NVM command/address CA_n may be provided to an NVM controller included in each heterogeneous memory device HMD, and the VM command/address CA_v may be provided to a volatile memory and an NVM controller that are included in each heterogeneous memory device HMD.

The SPD may include the device information DI about the nonvolatile memory module 700 and may provide the device information DI to the processor 101 (refer to FIG. 1).

The tag dedicated volatile memory TVM may operate in response to the VM command/address CA_v from the module controller MC. The tag dedicated volatile memory TVM may store tags TAG associated with pieces of data stored in volatile memories of the heterogeneous memory devices HMD. The tag dedicated volatile memory TVM may send and receive a tag “TAG” through the tag data line TDQ. In an embodiment, the tag data line TDQ may be shared by the module controller MC, the plurality of heterogeneous memory devices HMD, and the tag dedicated volatile memory TVM.

Although not shown in FIG. 24, the tag dedicated volatile memory TVM may be configured to be similar to the heterogeneous memory device HMD. For example, a volatile memory included in at least one of the plurality of heterogeneous memory devices HMD may be used as the tag dedicated volatile memory TVM.

In an embodiment, the nonvolatile memory module 700 of FIG. 24 may operate according to an operation method described with reference to FIGS. 3 to 21.

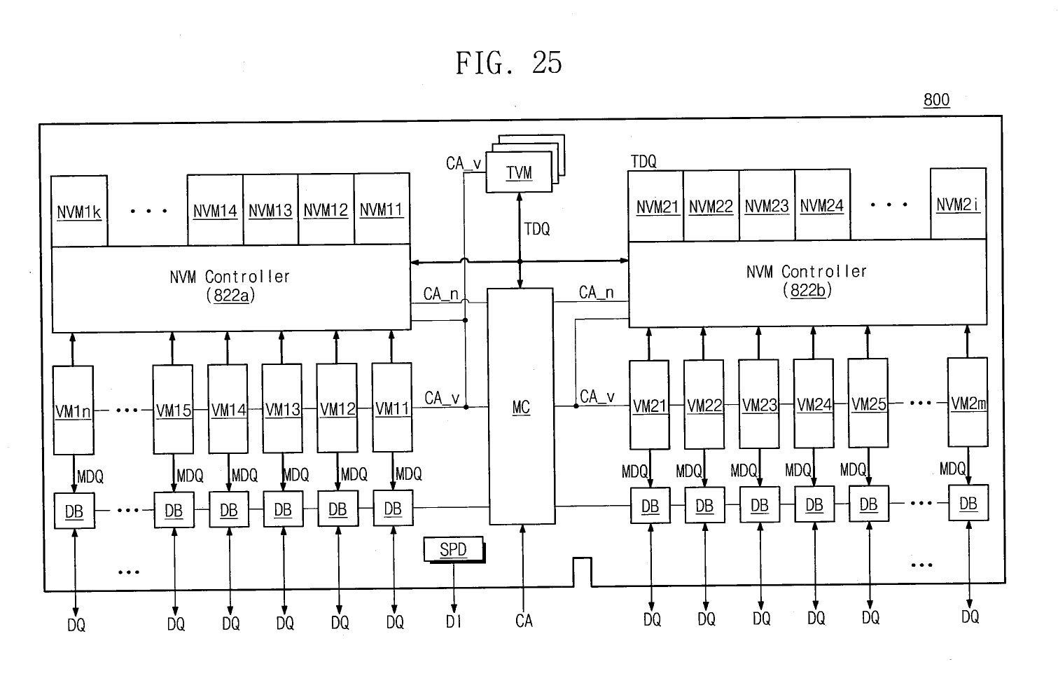

FIG. 25 is a block diagram illustrating the nonvolatile memory module of FIG. 1, according to another embodiment of the inventive concept. For descriptive convenience, a description of the above-described elements is omitted. Referring to FIG. 25, a nonvolatile memory module 800 may include the module controller MC, a plurality of volatile memories VM11 to VM1n and VM21 to VM2m, first and second NVM controllers 822a and 822b, a plurality of nonvolatile memories NVM11 to NVM1k and NVM21 to NVM2i, the tag dedicated volatile memory TVM, the SPD, and the plurality of data buffers DB. In an embodiment, the nonvolatile memory module 800 of FIG. 25 may have an LRDIMM structure.

Some (e.g., VM11 to VM1n) of the plurality of volatile memories VM11 to VM1n and VM21 to VM2m may be configured to share memory data lines MDQ with the first NVM controller 822a. The remaining volatile memories VM21 to VM2m may be configured to share the memory data lines MDQ with the second NVM controller 822b. Each of the plurality of volatile memories VM11 to VM1n and VM21 to VM2m may be configured to share the memory data line MDQ with a corresponding one of the plurality of data buffers DB.

Some (e.g., NVM11 to NVM1k) of the plurality of nonvolatile memories NVM11 to NVM1k and NVM21 to NVM2i may be configured to operate in response to control of the first NVM controller 822a. The remaining nonvolatile memories NVM21 to NVM2i may be configured to operate in response to control of the second NVM controller 822b.

The tag dedicated volatile memory TVM may be configured to share the tag data line TDQ with the module controller MC, the first NVM controller 822a, and the second NVM controller 822b.

In an embodiment, each of elements illustrated in FIG. 25 may be implemented with a plurality of semiconductor chips, and at least some of the semiconductor chips may be implemented in one package. For example, each of the plurality of volatile memories VM11 to VM1n and VM21 to VM2m, the plurality of nonvolatile memories NVM11 to NVM1k and NVM21 to NVM2i, the first NVM controller 822a, and the second NVM controller 822b may be implemented with separate semiconductor chips. Some of the plurality of volatile memories VM11 to VM1n and VM21 to VM2m, the plurality of nonvolatile memories NVM11 to NVM1k and NVM21 to NVM2i, the first NVM controller 822a, and the second NVM controller 822b may be implemented in one package.

For example, some (e.g., VM11 to VM1n) of the plurality of volatile memories VM11 to VM1n and VM21 to VM2m may be implemented in one package, and the first NVM controller 822a and some (e.g., NVM11 to NVM1k) of the plurality of nonvolatile memories NVM11 to NVM1k and NVM21 to NVM2i may be implemented in another package.

In an embodiment, the tag dedicated volatile memory TVM may include a plurality of semiconductor chips. For example, the tag dedicated volatile memory TVM may include a plurality of tag dedicated volatile memory chips, each of which stores the same tag, ECC, and dirty information. In this case, even though an operation of any one tag dedicated volatile memory chip is abnormal, it may be possible to write or output normally tag information, ECC information, and dirty information through another tag dedicated volatile memory. In an embodiment, a package in which the tag dedicated volatile memory TVM is included may be different from a package in which other elements are included. Alternatively, the tag dedicated volatile memory TVM may be implemented in a package in which at least some of other elements are included.

In an embodiment, the nonvolatile memory module 800 of FIG. 25 may operate according to an operation method described with reference to FIGS. 3 to 21.

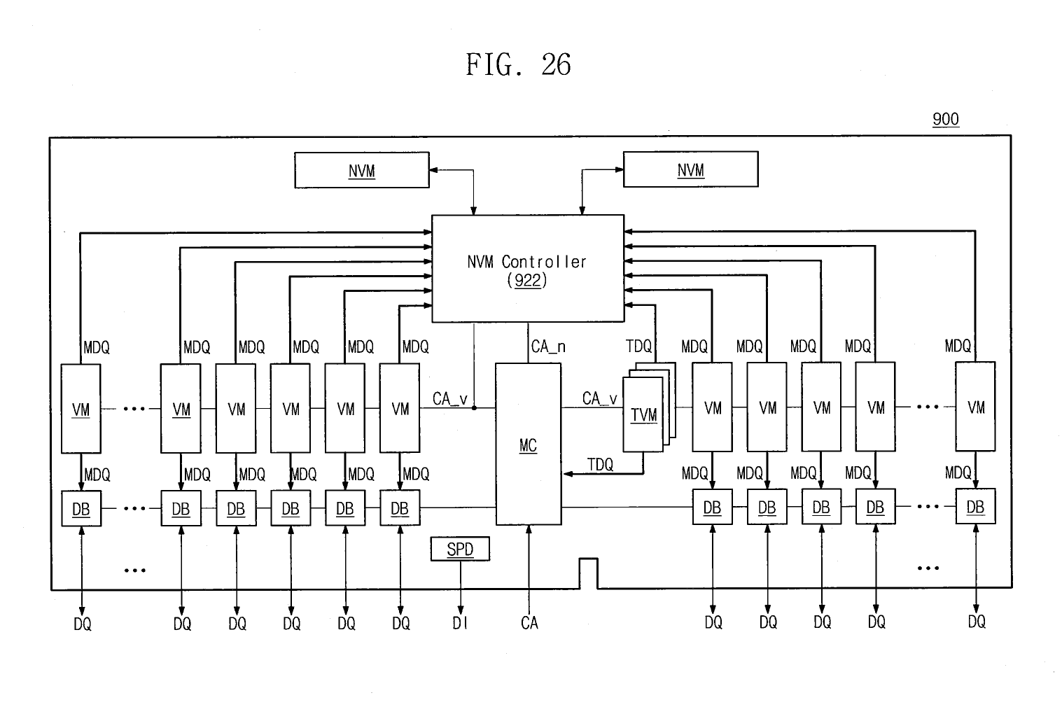

FIG. 26 is a block diagram illustrating a nonvolatile memory module of FIG. 1 according to another embodiment of the inventive concept. Referring to FIG. 26, a nonvolatile memory module 900 may include the module controller MC, a plurality of volatile memories VM, an NVM controller 922, nonvolatile memories NVM, the tag dedicated volatile memory TVM, the SPD, and the plurality of data buffers DB. For descriptive convenience, a detailed description of the above-described elements is omitted. In an embodiment, the nonvolatile memory module 900 of FIG. 26 may have an LRDIMM structure.

Unlike the nonvolatile memory module 800 of FIG. 25, the nonvolatile memory module 900 of FIG. 26 may control the nonvolatile memories NVM through one NVM controller 922. That is, each of the plurality of volatile memories VM is configured to share a memory data line MDQ with the NVM controller 922.

The tag dedicated volatile memory TVM is configured to share the tag data line TDQ with the module controller MC and the NVM controller 922. As described above, on the basis of the VM command/address CA_v, the tag described volatile memory TVM may store a tag “TAG” or may output a tag “TAG” stored therein.

In an embodiment, the nonvolatile memory module 900 of FIG. 26 may operate according to an operation method described with reference to FIGS. 3 to 21.

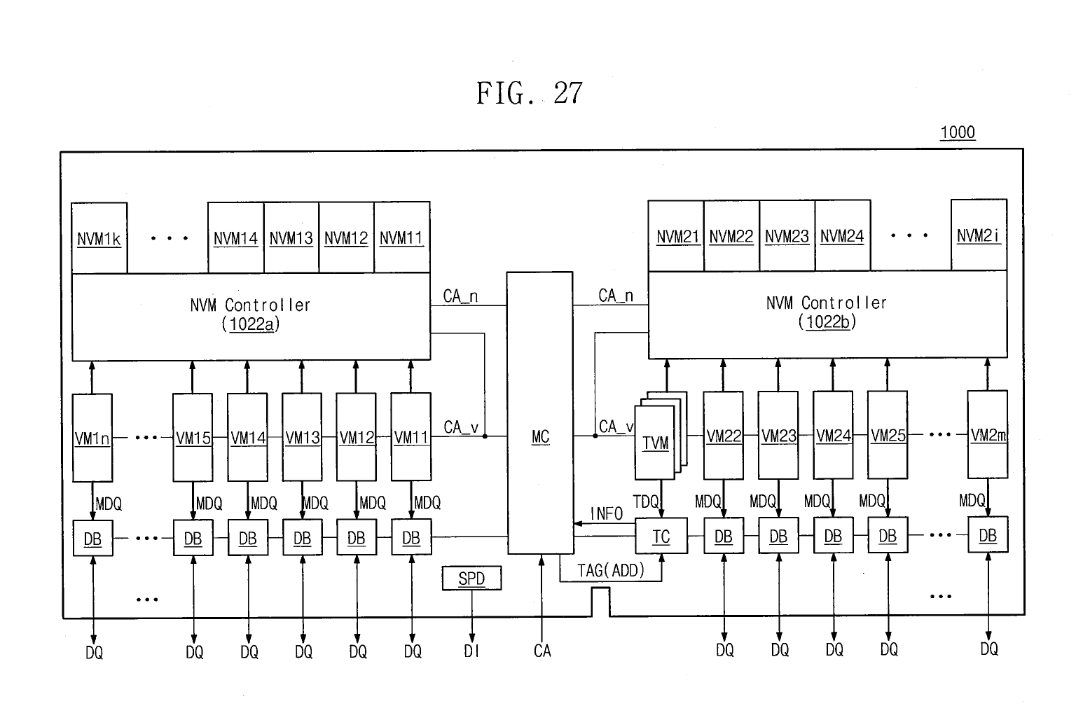

FIG. 27 is a block diagram illustrating a nonvolatile memory module of FIG. 1 according to another embodiment of the inventive concept. Referring to FIGS. 1 and 27, a nonvolatile memory module 1000 may include the module controller MC, a plurality of volatile memories VM11 to VM1n and VM21 to VM2m, first and second NVM controllers 1022a and 1022b, a plurality of nonvolatile memories NVM11 to NVM1k and NVM21 to NVM2i, the tag dedicated volatile memory TVM, the SPD, the plurality of data buffers DB, and a tag control circuit TC. For descriptive convenience, a description of the above-described elements is omitted. In an embodiment, the nonvolatile memory module 1000 of FIG. 27 may have an LRDIMM structure.

Unlike the nonvolatile memory modules 700, 800, and 900 of FIGS. 24 to 26, the nonvolatile memory module 1000 of FIG. 27 may further include the tag control circuit TC. The control circuit TC is configured to share the tag data line TDQ with the tag dedicated volatile memory TVM. That is, the tag control circuit TC may receive a tag “TAG” from the tag dedicated volatile memory TVM through the tag data line TDQ or may send the tag “TAG” to the tag dedicated volatile memory TVM through the tag data line TDQ.

The module controller MC may control the tag control circuit TC so as to determine whether a cache hit or a cache miss is generated, and the tag control circuit TC may output the determination result as cache information INFO. For example, the tag control circuit TC may receive the tag “TAG” from the tag dedicated volatile memory TVM under control of the module controller MC. The tag control circuit TC may determine whether the cache miss or cache hit is generated, by comparing a tag “TAG” (or an address ADD) from the module controller MC with a tag “TAG” from the tag dedicated volatile memory TVM.

In an embodiment, the tag control circuit TC may be implemented in software or hardware, and the tag control circuit TC may be included in the module controller MC or may be included in each of the first and second NVM controllers 1022a and 1022b.

In an embodiment, the nonvolatile memory module 1000 of FIG. 27 may operate according to an operation method described with reference to FIGS. 3 to 21.

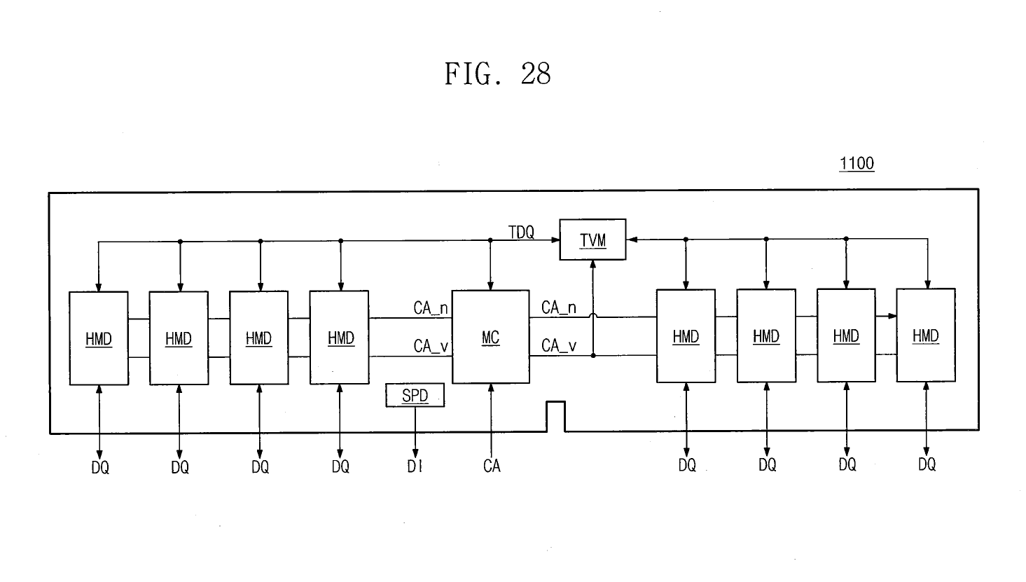

FIG. 28 is a block diagram illustrating the nonvolatile memory module of FIG. 1, according to another embodiment of the inventive concept. Referring to FIG. 28, a nonvolatile memory module 1100 includes the module controller MC, the plurality of heterogeneous memories HMD, the tag dedicated volatile memory TVM, and the SPD. For descriptive convenience, a detailed description of the above-described elements is omitted.

Unlike the nonvolatile memory module 700 of FIG. 24, the nonvolatile memory module 1100 illustrated in FIG. 28 does not include a plurality of data buffers. That is, the nonvolatile memory module 1100 may have a registered DIMM (RDIMM) structure.

Each of the plurality of heterogeneous memories HMD is directly connected with the data line DQ. In an embodiment, in each of the plurality of heterogeneous memories HMD, an NVM controller controlling a nonvolatile memory and a volatile memory may be configured to share the data line DQ.

In an embodiment, the processor 101 (refer to FIG. 1) may receive the device information DI from the SPD of the nonvolatile memory module 1100 and may control the nonvolatile memory module 1100 based on the received device information DI. In this case, the device information DI may include the above-described operation information of the nonvolatile memory module 1100 such as a read latency RL and a write latency WL. That is, even though a volatile memory and an NVM controller included in each heterogeneous memory device HMD share a data line DQ and exchange data with each other through the data line DQ independently of a request of the processor 101, since the processor 101 controls the nonvolatile memory module 1100 based on the device information, the processor 101 may perform normally a read or write operation with respect to the nonvolatile memory module 1100.

In an embodiment, the nonvolatile memory module 1100 of FIG. 28 may operate according to an operation method described with reference to FIGS. 3 to 21.

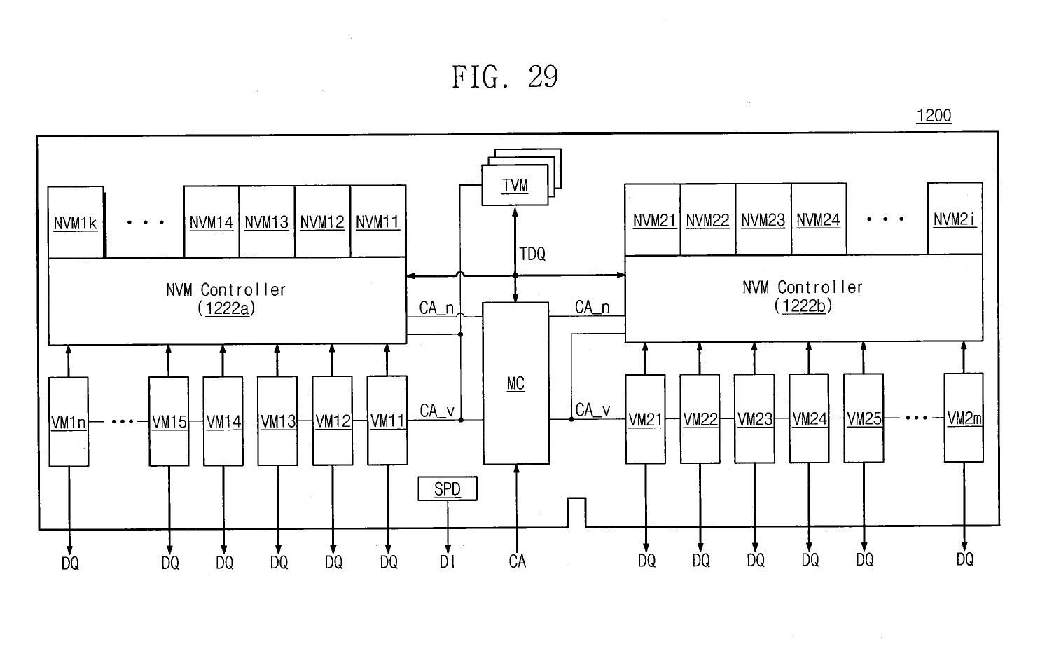

FIG. 29 is a block diagram illustrating the nonvolatile memory module of FIG. 1, according to another embodiment of the inventive concept. Referring to FIG. 29, a nonvolatile memory module 1200 includes the module controller MC, the plurality of volatile memories VM11 to VM1n and VM21 to VM2m, first and second NVM controllers 1222a and 1222b, the plurality of nonvolatile memories NVM11 to NVM1k and NVM21 to NVM2i, the tag dedicated volatile memory TVM, and the SPD. For descriptive convenience, a detailed description of the above-described elements is omitted.

Unlike the nonvolatile memory module 800 of FIG. 25, the nonvolatile memory module 1200 of FIG. 29 may not include a plurality of data buffers DB. That is, the nonvolatile memory module 1200 may have an RDIMM structure. In this case, some (e.g., VM11 to VM1n) of the plurality of volatile memories VM11 to VM1n and VM21 to VM2m may share the data line DQ with the first NVM controller 1222a, and the remaining volatile memories (e.g., VM21 to VM2m) may share the data line DQ with the second NVM controller 1222b.

As in a description given with reference to FIG. 28, even though the data line DQ is shared by the plurality of volatile memories VM11 to VM1n and VM21 to VM2m and the first and second NVM controllers 1222a and 1222b, since the processor 101 operates based on the device information DI from the SPD, the processor 101 may control normally the nonvolatile memory module regardless of data exchange between the volatile memories VM11 to VM1n and VM21 to VM2m and the first and second NVM controllers 1222a and 1222b.

In an embodiment, the nonvolatile memory module 1200 of FIG. 29 may operate according to an operation method described with reference to FIGS. 3 to 21.

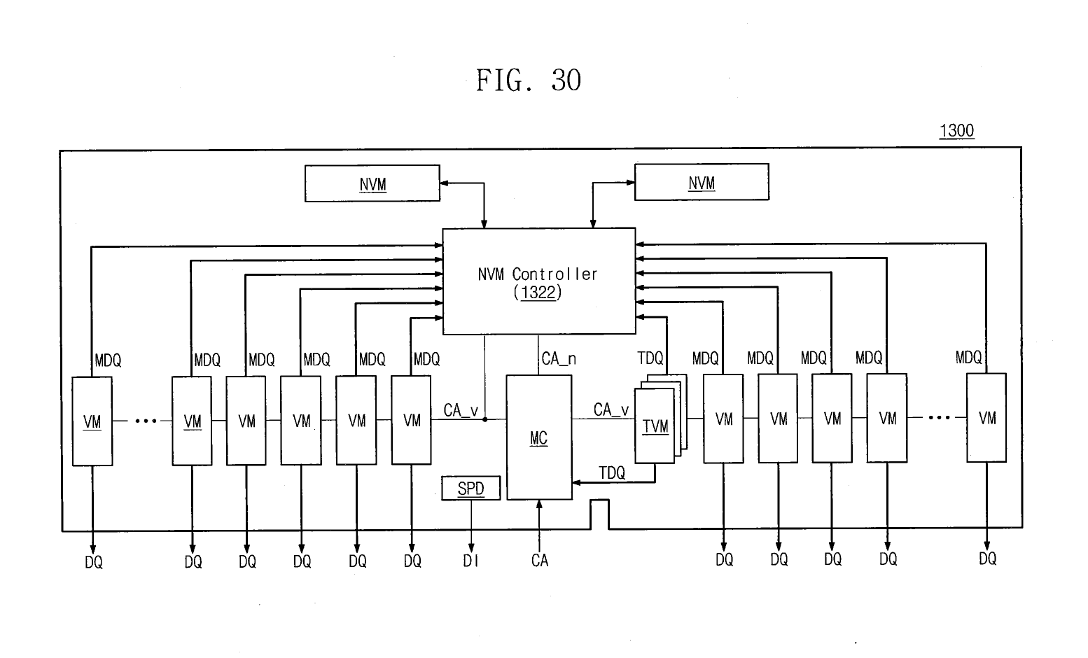

FIG. 30 is a block diagram illustrating the nonvolatile memory module of FIG. 1, according to another embodiment of the inventive concept. Referring to FIG. 30, a nonvolatile memory module 1300 includes the module controller MC, a plurality of volatile memories VM, an NVM controller 1322, nonvolatile memories NVM, the tag dedicated volatile memory TVM, and the SPD. For descriptive convenience, a detailed description of the above-described elements is omitted.

Unlike the nonvolatile memory module 900 of FIG. 26, the nonvolatile memory module 1300 of FIG. 30 may not include a plurality of data buffers DB. That is, the nonvolatile memory module 1300 may have an RDIMM structure. The plurality of volatile memories VM is configured to share data lines DQ with the NVM controller 1322.

As described above, since the processor 101 operates based on the device information DI from the SPD, the processor 101 may control normally the nonvolatile memory module 1300 regardless of data exchange between the plurality of volatile memories VM and the NVM controller 1322.

The above-described nonvolatile memory modules are only examples, and embodiments are not limited thereto. Nonvolatile memory modules according to embodiments of the inventive concept may be variously combined or modified.

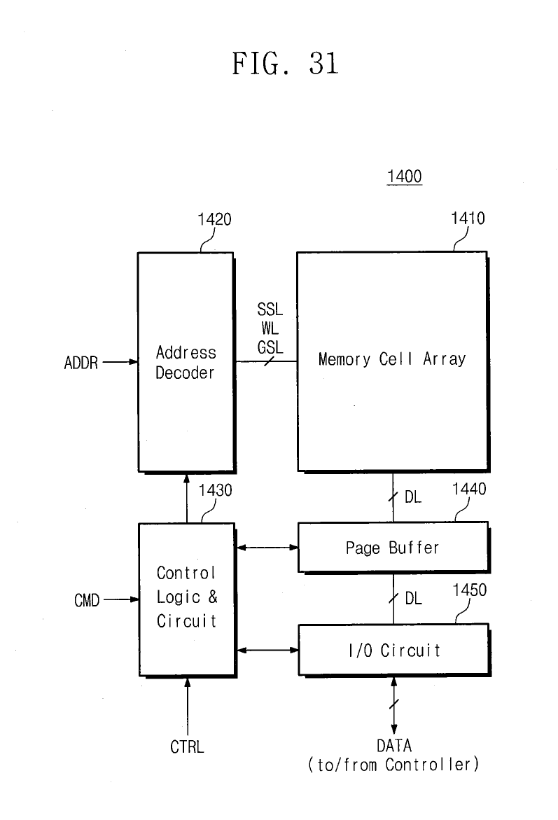

FIG. 31 is a block diagram illustrating a nonvolatile memory included in a nonvolatile memory module, according to the inventive concept; Referring to FIG. 31, a nonvolatile memory 1400 may include a memory cell array 1410, an address decoder 1420, a control logic circuit 1430, a page buffer 1440, and an input/output circuit 1450.

The memory cell array 1410 includes a plurality of memory blocks, each of which has a plurality of memory cells. The plurality of memory cells may be connected with a plurality of word lines WL. Each memory cell may be a single level cell (SLC) storing one bit or a multi-level cell (MLC) storing at least two bits.

The address decoder 1420 may receive and decode an address ADDR from the NVM controller 122 (refer to FIG. 2). In an embodiment, the address ADDR received from the NVM controller 122 may be a physical address indicating a physical location of a storage region of the nonvolatile memory 1400. The address decoder 1420 may select at least one of the word lines WL based on the decoded address and may drive a voltage of the selected word line.

The control logic circuit 1430 may control the address decoder 1420, the page buffer 1440, and the input/output circuit 1450 in response to a command CMD and a control logic CTRL received from the NVM controller 112 (refer to FIG. 2).

The page buffer 1440 is connected with the memory cell array 1410 through a plurality of bit lines BL and is connected with the input/output circuit 1450 through a plurality of data lines DL. The page buffer 1440 may store data stored in the memory cell array 1410 by sensing voltages of the plurality of bit lines BL. Alternatively, the page buffer 1440 may adjust voltages of the plurality of bit lines BL based on data received through the plurality of data lines DL.

Under control of the control logic circuit 1430, the input/output circuit 1450 may receive data from the NVM controller 122 (refer to FIG. 2) and may send the received data to the page buffer 1440. Alternatively, the input/output circuit 1450 may receive data from the page buffer 1440 and may send the received data to the NVM controller 122.

In an embodiment, the NVM controller 122 may generate the address ADDR, the command CMD, and the control signal CTRL based on an NVM command/address CA_n from the module controller 110 (refer to FIG. 2).

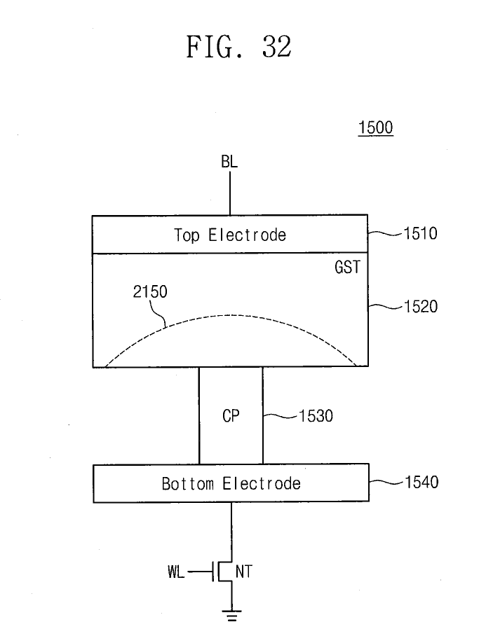

FIG. 32 is a view illustrating a cell structure and a physical property of a phase change memory device as an example of a nonvolatile memory device according to an embodiment of the inventive concept. Referring to FIG. 32, a memory cell 1500 includes a variable resistor and an access transistor NT. The variable resistor is composed of a top electrode 1510, a phase change material 1520, a contact plug 1530, and a bottom electrode 1540. The top electrode 1510 is connected to a bit line BL. The bottom electrode 1540 is connected between the contact plug 1530 and the access transistor NT. The contact plug 1530 is formed of a conductive material (e.g., TiN) and is also called a “heater plug”. The phase change material 1520 is between the top electrode 1510 and the contact plug 1530. A phase of the phase change material 1520 may change according to an amplitude, a duration, a fall time, etc. of a supplied current pulse. The phase of the phase change material 1520 corresponding to “set” or “reset” is determined by an amorphous volume 2150 as illustrated in FIG. 32. In general, an amorphous phase and a crystal phase correspond to a reset phase and a set phase, respectively. As a phase of the phase change material 1520 progresses from the amorphous phase to the crystal phase, the amorphous volume decreases. The phase change material 1520 has resistance that varies according to the formed amorphous volume 2150. That is, a value of written data is determined according to the amorphous volume 2150 of the phase change material 1520 formed according to different current pulses.

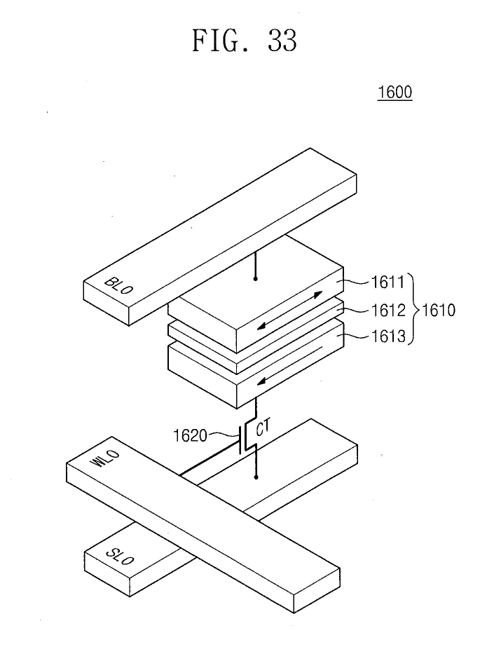

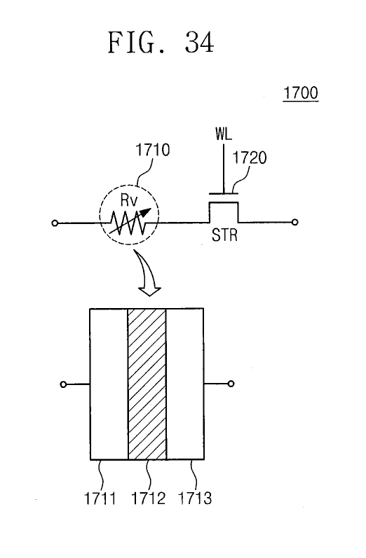

FIGS. 33 to 34 are views illustrating a memory cell included in a nonvolatile memory according to an embodiment of the inventive concept. A three-dimensional cell structure of a spin-transfer torque magnetic random access memory (STT-MRAM) is illustrated in FIG. 33. A cell structure of a magnetoresistive RAM will be described with reference to FIG. 34.

A memory cell 1600 of a STT-MRAM is illustrated in FIG. 33. The memory cell 1600 may include a magnetic tunnel junction (MTJ) element 1610 and a cell transistor (CT) 1620. A word line WL0 is connected with a gate of the cell transistor 1620. A first end of the cell transistor 1620 is connected with a bit line BL0 through the MTJ element 1610. A second end of the cell transistor 1620 is connected to a source line SL0.

The MTJ element 1610 may include a pinned layer 1613, a free layer 1611, and a tunnel layer 1612 interposed therebetween. A magnetization direction of the pinned layer 1613 may be fixed, and a magnetization direction of the free layer 1611 may be the same as or opposite to the magnetization direction of the pinned layer under a condition. The memory cell 1600 may further include, for example, an anti-ferromagnetic layer (not shown) to pin the magnetization direction of the pinned layer 1613.

To write data in the memory cell 1600, the cell transistor 1620 is turned on by applying a voltage to the word line WL0, and a write current is applied between the bit line BL0 and the source line SL0. To read data from the memory cell 1600, the cell transistor 1620 is turned on by applying a voltage to the word line WL0, and a read current is applied in a direction from the bit line BL0 to the source line SL0. In this case, data stored in the memory cell 1600 is determined according to a resistance value measured under the above-described condition.

FIG. 34 is a circuit diagram illustrating a memory cell 1700 of a magnetoresistive memory device. Referring to FIG. 34, the memory cell 1700 of the magnetoresistive memory device includes a variable resistance element (Rv) 1710 and a selection element (STR) 1720.

The variable resistance element 1710 includes a variable resistance material for storing data. On the basis of a voltage of a word line WL, the selection element 1720 supplies a current to the variable resistance element 1710 or blocks a current supplied thereto. The selection element 1720 is implemented with an NMOS transistor as illustrated in FIG. 34. However, the selection element 1720 may be implemented with one of switch elements such as a PMOS transistor and a diode.

The variable resistance element 1710 includes a pair of electrodes 1711 and 1713 and a data storage film 1712 formed therebetween. The data storage film 1712 may be formed of a bipolar resistance storage material or a unipolar resistance storage material. The bipolar resistance storage material is programmed to a set or reset state by a pulse polarity. The unipolar resistance storage material may be programmed to a set or reset state by the same pulse polarity. The unipolar resistance storage material includes single transition metal oxide such as NiOx or TiOx. The bipolar resistance storage material includes pervoskite-based materials.

The STT-MRAM and RRAM are described as an example of a memory cell included in a nonvolatile memory. However, it should be understood that the memory cell of the nonvolatile memory according to an embodiment of the inventive concept is not limited thereto. That is, the memory cell of the nonvolatile memory may be provided in the form of one of a flash memory, a PRAM, an MRAM, or a ferroelectric RAM (FRAM).

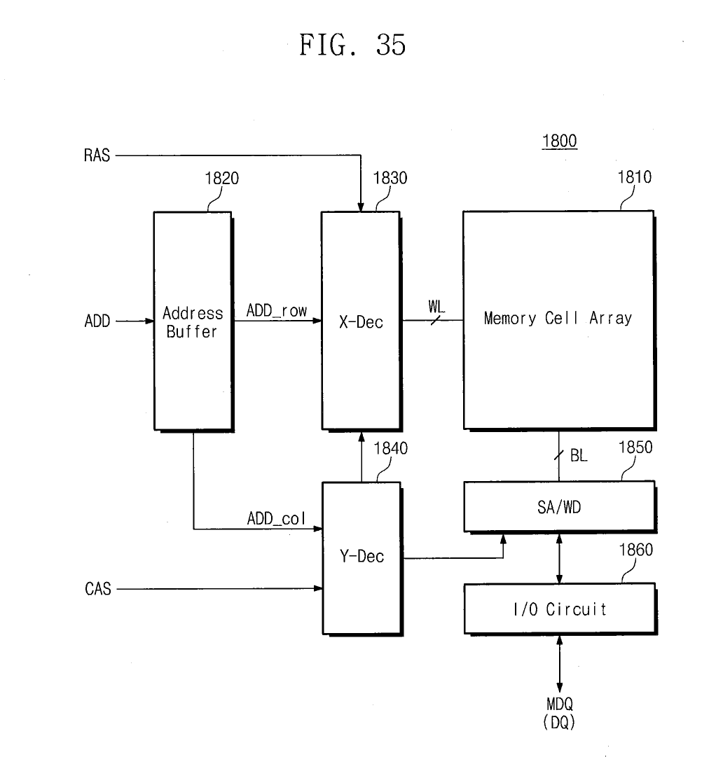

FIG. 35 is a block diagram illustrating a volatile memory of the nonvolatile memory module according to an embodiment of the inventive concept. Referring to FIG. 35, a volatile memory 1800 may include a memory cell array 1810, an address buffer 1820, a row decoder (X-decoder) 1830, a column decoder (Y-decoder) 1840, a sense amplifier and write driver 1850, and an input/output circuit 1860.

The memory cell array 1810 may include a plurality of memory cells, which are connected with a plurality of word lines WL and a plurality of bit lines BL. The plurality of memory cells may be located at intersections of the word lines and the bit lines, respectively. In an embodiment, each of the plurality of memory cells may include a storage capacitor and an access transistor.

The address buffer 1820 may receive and temporarily store an address ADD from the module controller 110 (refer to FIG. 2). In an embodiment, the address buffer 1820 may provide a row address ADD_row of the received address ADD to the X-decoder 1830 and may provide a column address ADD_col thereof to the Y-decoder 1840.

The X-decoder 1830 is connected with the memory cell array 1810 through the bit lines BL. The X-decoder 1830 may activate at least one, which corresponds to the row address A_row, from among the plurality of word lines WL in response to a row address strobe signal RAS from the module controller 110.

The Y-decoder 1840 may receive the column address ADD_col from the address buffer 1820. When a column address strobe signal CAS is received, the Y-decoder 1840 may control the sense amplifier and write driver 1850 based on the column address ADD_col.

The sense amplifier and write driver 1850 is connected with the memory cell array 1810 through the plurality of bit lines BL. The sense amplifier and write driver 1850 may sense a voltage change of each bit line. Alternatively, the sense amplifier and write driver 1850 may adjust voltages of the plurality of bit lines based on data received from the input/output circuit 1860.

The input/output circuit 1860 may receive data from the sense amplifier and write driver 1850 and may output the received data through the memory data line MDQ (or the data line DQ). Alternatively, the input/output circuit 1860 may receive data through the memory data line MDQ (or the data line DQ) and may provide the received data to the sense amplifier and write driver 1850.

In an embodiment, the address ADD may be an address included in the VM command/address CA_v provided from the module controller 110 (refer to FIG. 2). The row address strobe signal RAS and the column address strobe signal CAS may be signals that are included in the VM command/address CA_v provided from the module controller 110.

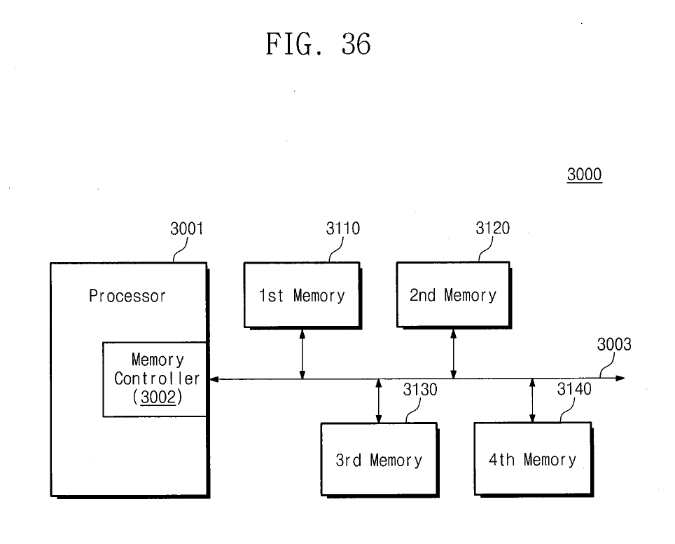

FIG. 36 is a block diagram illustrating a user system to which the nonvolatile memory module according to an embodiment of the inventive concept is applied. Referring to FIG. 36, a user system 3000 may include a processor 3001 and a plurality of memories 3110 to 3140.

The processor 3001 may include a memory controller 3002. The memory controller 3002 may communicate with the memories 3110 and 3140 through one bus 3003. In an embodiment, the bus 3003 may include dedicated buses that are respectively connected with the plurality of memories 3110 to 3140 or a shared bus shared by the plurality of memories 3110 to 3140. In an embodiment, the bus 3003 may include at least one of the data line DQ, the data line DQ, the memory data line MDQ, and the tag data line TDQ described with reference to FIGS. 1 to 36.

In an embodiment, at least some of the plurality of memories 3110 to 3140 may be nonvolatile memory modules described with reference to FIGS. 1 to 36 or may operate according to an operation method described with reference to FIGS. 1 to 36.

Alternatively, each of at least some of the plurality of memory modules 3110 to 3140 may include a nonvolatile memory, and each of the remaining memory modules thereof may include a volatile memory. A memory module including a volatile memory may be used as a cache memory of a memory module including a nonvolatile memory. That is, as described with reference to FIGS. 1 to 36, some of the plurality of memory modules 3110 to 3140 may be used as a main memory of the user system 3000, and the remaining memory modules thereof may be used as a cache memory. Each of memories used as a cache memory may be a volatile memory described with reference to FIGS. 1 to 35 or may operate the same as a volatile memory described with reference to FIGS. 1 to 35.

In an embodiment, the memory controller 3002 may be a memory controller or a controller described with reference to FIGS. 1 to 35 or may operate the same as a memory controller described with reference to FIGS. 1 to 35.

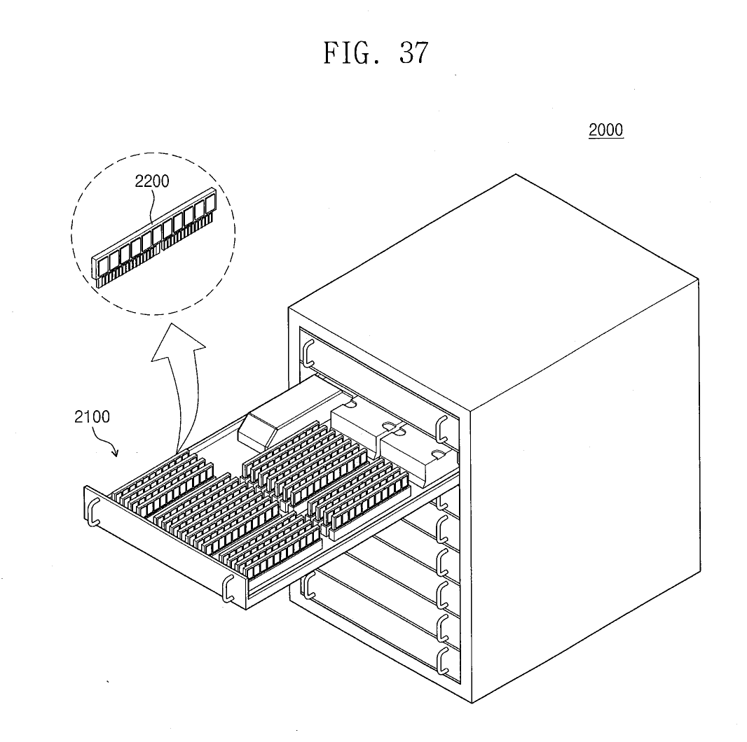

FIG. 37 is a view illustrating a server system to which the nonvolatile memory system according to an embodiment of the inventive concept is applied. Referring to FIG. 36, a server system 2000 may include a plurality of server racks 2100. Each of the server racks 2100 may include a plurality of nonvolatile memory modules 2200. The nonvolatile memory modules 2200 may be directly connected with processors that are respectively included in the server racks 2100. For example, the nonvolatile memory modules 2200 may have the form of a dual in-line memory module and may be mounted on a DIMM socket electrically connected with a processor so as to communicate with the processor. In an embodiment, the nonvolatile memory modules 2200 may be used as storage of the server system 2000. In an embodiment, each of the plurality of nonvolatile memory modules 2200 may be a nonvolatile memory module described with reference to FIGS. 1 to 35 or may operate according to an operation method described with reference to FIGS. 1 to 35.

According to an embodiment of the inventive concept, a nonvolatile memory module may include a nonvolatile memory; a volatile memory operating as a cache memory of the nonvolatile memory; and a module controller configured to output data stored in the volatile memory in response to a read command and an address from an external device and output a transaction identification corresponding to the address or information indicating whether the data is valid, wherein the information indicating whether the data is valid and the transaction identification are output via the same signal line.

According to an embodiment, the nonvolatile memory module may further include a nonvolatile memory controller configured to share a data line with the volatile memory and control the nonvolatile memory.

According to an embodiment, the module controller or the nonvolatile memory controller may determine whether a cache hit or a cache miss is generated with respect to data corresponding to the address, with reference to the address and a tag stored in the volatile memory.

According to an embodiment, the module controller may determine whether the data is valid, based on a result of performing a cache check operation with respect to the address.

According to an embodiment, if the result indicates that the cache hit is generated, the module controller may output the information by using a value indicating whether the data is valid.

According to an embodiment, if the result indicates that the cache miss is generated, the module controller may output the information by using a value indicating whether the data is invalid and output the transaction identification.

According to an embodiment, the module controller may allocate transaction identifications, which monotonically increase, to a plurality of data determined as the cache miss.

According to an embodiment, the module controller may output message information indicating whether data corresponding to the address is prepared, based on the result of the cache check operation with respect to the address, and the message information may be output without synchronization with the data.

According to an embodiment, the message information may be output via a signal line different from that of the transaction identification and the information indicating whether the data is valid.

According to an embodiment, the message information may include a transaction identification corresponding to data that is cached in the volatile memory from the nonvolatile memory.

According to an embodiment, the module controller may output cache information including tag information corresponding to the address in synchronization with the data.

According to another embodiment of the inventive concept, an operation method of a memory module that include a volatile memory device and a nonvolatile memory device may include receiving a read command and an address from the outside; comparing the address with a tag stored in the volatile memory device to detect whether data corresponding to the address is cached in the volatile memory device; and outputting validity of the data or a transaction identification corresponding to the address in synchronization with the data based on the comparison result, wherein the validity or transaction identification is output via a signal line different from that of the data.

According to an embodiment, if the comparison result indicates a cache hit, a value indicating that the data is valid may be output as the validity without the transaction identification.

According to an embodiment, if the comparison result indicates a cache miss, a value indicating that the data is invalid may be output as the validity, and the transaction identification may be output.

According to an embodiment, the method may further include outputting message information indicating whether data corresponding to the address is prepared, after data corresponding to the cache miss is stored in the volatile memory.

According to an embodiment, the message information may be output without synchronization with the data.

According to an embodiment, the message information may include a transaction identification corresponding to the data.

According to an embodiment, the method may further include receiving an additional read command and an address associated with the data from the outside, after the message information is output.

According to an embodiment, the method may further include outputting a tag of the volatile memory device or cache information including whether the data is dirty, in synchronization with the data.

According to still another embodiment of the inventive concept, a memory module may include a first memory device; a second memory device of which an access speed is slower than that of the first memory device; and a memory controller, configured to output data, which is based on an access speed of the first memory device, in response to a read command and an address from the outside and output a transaction identification corresponding to the address or information indicating whether the data is valid, wherein the information indicating whether the data is valid and the transaction identification are output via the same signal line.

According to embodiments of the inventive concept, a nonvolatile memory module having a great capacity and high performance is provided by using a nonvolatile memory device and a volatile memory device. The nonvolatile memory module may be used as a main memory of a system, thereby improving the performance of the nonvolatile memory module and reducing a manufacturing cost thereof.

While the inventive concept has been described with reference to exemplary embodiments, it will be apparent to those skilled in the art that various changes and modifications may be made without departing from the spirit and scope of the inventive concept. Therefore, it should be understood that the above embodiments are not limiting, but illustrative.

1.-8. (canceled)

9. A method of accessing volatile memory devices, nonvolatile memory devices, and a controller controlling the volatile memory devices and the nonvolatile memory devices, the method comprising:
receiving, by the controller, a row address associated with the volatile memory devices and the nonvolatile memory devices through first lines at a first timing;
receiving, by the controller, an extended address associated with the nonvolatile memory devices through second lines at a second timing; and
receiving, by the controller, a column address associated with the nonvolatile memory devices and the volatile memory devices through third lines at a third timing.

10. The method of claim 9, further comprising:
receiving, through command input lines, an activation extension command indicating that the extended address is transmitted at the second timing.

11. The method of claim 10, further comprising:
receiving, through an auto precharge input line, an additional activation extension command indicating that the extended address is transmitted at the second timing.

12. The method of claim 9, further comprising:
receiving an active command at the first timing;
receiving an activation extension command at the second timing; and
receiving a read or write command at the third timing.

13. The method of claim 12, wherein another command is prohibited from being received between the first timing and the second timing.

14. The method of claim 12, wherein at the second timing, a signal of a “RAS_n/A16” line, a signal of a “CAS_n/A15” line, and a signal of a “WE_n/A14” line are of a low level, a high level, and a high level, respectively.

15. The method of claim 14, wherein a signal of an “A10/AP” line is of a high level at the second timing.

16. The method of claim 9, wherein the second lines include 0th to ninth address lines.

17. The method of claim 9, wherein at the second timing, each of bank group address lines, bank address input lines, chip identifier lines, a burst chop signal line, and 11th, 13th, and 17th address lines has any value that is defined by one of a high level and a low level.

18. The method of claim 9, further comprising:
reading, by the controller, a tag associated with the row address and the column address from the volatile memory devices; and
accessing, by the controller, the volatile memory devices if the tag is the same as the extended address.

19. The method of claim 18, further comprising:
writing, by the controller, a dirty flag associated with the row address and the column address in the volatile memory devices to be a dirty state when the controller writes data in the volatile memory devices.

20. The method of claim 19, further comprising:
writing, by the controller, the extended address as a tag associated with the row address and the column address in the volatile memory devices when the controller writes data in the volatile memory devices.

21. The method of claim 18, further comprising:
reading, by the controller, a dirty flag associated with the row address and the column address from the volatile memory devices if the tag is different from the extended address; and
if the dirty flag indicates a dirty state, reading, by the controller, data based on the row address and the column address and writing the read data in the nonvolatile memory devices based on the row address, the column address, and the extended address.

22. The method of claim 21, further comprising:
during a read operation, after a write operation is completed with respect to the nonvolatile memory devices, reading, by the controller, second data from the nonvolatile memory devices based on the row address, the column address, and the extended address and writing the second data in the volatile memory devices based on the row address and the column address.

23. The method of claim 21, further comprising:
during a write operation, after a write operation is completed with respect to the nonvolatile memory devices, writing, by the controller, second data in the volatile memory devices based on the row address and the column address and writing the second data in the nonvolatile memory devices based on the row address, the column address, and the extended address.

24. A memory module comprising:
nonvolatile memory devices;
volatile memory devices; and
a controller configured to control the nonvolatile memory devices and the volatile memory devices,
wherein the controller receives a row address associated with the volatile memory devices and the nonvolatile memory devices through first lines at a first timing, receives an extended address associated with the nonvolatile memory devices through second lines at a second timing, and receives a column address associated with the nonvolatile memory devices and the volatile memory devices through third lines at a third timing.

25. A method of accessing a cache memory of a first type and a main memory of a second type, the method comprising:
sending a common address to the cache memory of the first type and the main memory of the second type through address lines associated with the cache memory of the first type by using a plurality of sequences; and
sending an extended address to the main memory of the second type through the address lines associated with the cache memory of the first type by using at least one sequence.

26. The method of claim 25, wherein the common address and the extended address are converted into an internal address of the main memory of the second type and the converted internal address is transmitted to the main memory of the second type through separate lines independent of the address lines.

27. The method of claim 25, wherein the at least one sequence is executed among the plurality of sequences.

28. The method of claim 25, further comprising:
sending a command to the cache memory of the first type and the main memory of the second type through command lines associated with the cache memory of the first type,
wherein the command is converted into a command of the main memory of the second type and the converted command is transmitted to the main memory of the second type through a separate line independent of the command line.
